(19) United States
(12) Patent Application Publication
(10) Pub. No.: US 2025/0160172 A1
(43) Pub. Date: May 15, 2025

(54) STACKED BODY FOR DISPLAY DEVICES AND DISPLAY DEVICE

(71) Applicant: DAI NIPPON PRINTING CO., LTD., Tokyo (JP)

(72) Inventors: Kenichi ONODERA, Tokyo (JP); Jun SATO, Tokyo (JP); Kiyohiro TAKACHI, Tokyo (JP); Saori KAWAGUCHI, Tokyo (JP)

(21) Appl. No.: 18/686,343

(22) PCT Filed: Aug. 26, 2022
(86) PCT No.: PCT/JP2022/032184

§ 371 Date: Oct. 1, 2024

(30) Foreign Application Priority Data
Aug. 27, 2021 (JP) 2021-138608

(51) Int. Cl. H10K 59/80

(52) U.S. Cl. CPC H10K 59/873; H10K 59/8792

(57) ABSTRACT

The present disclosure provides a stacked body for a display device comprising a polyimide substrate, and a functional layer including an ultraviolet absorber, placed on one surface of the polyimide substrate, wherein a difference of a crack elongation of the stacked body for a display device measured by a predetermined method, before and after a predetermined light resistance test, is 0.6 or less.

### TECHNICAL FIELD

The present disclosure relates to a stacked body for a display device, and a display device using the same.

### BACKGROUND ART

For example, a stacked body provided with a functional layer having various properties such as a hard coating property, a scratch resistance, antireflection property, an antiglare property, an antistatic property, and an antifouling property, is placed on the surface of a display device.

The stacked body includes a substrate layer, and a functional layer placed on one surface of the substrate layer. In recent years, in terms of, for example, processability, light weight, thinness, and flexibility, as the substrate layer, glass substrates are being replaced with resin substrates. In particular, the use of polyimide substrates with improved transparency has been studied because of their excellent mechanical strength and heat resistance (for example, Patent Documents 1 and 2).

Recently, flexible displays such as foldable displays, rollable displays, and bendable displays have been attracting attention, and the development of the stacked body placed on the surface of the flexible displays has been actively promoted.

The stacked body used for a flexible display is required to be flexible enough to follow the movement of the flexible display, and to have bending resistance so as not to crack even when bent.

For example, Patent Document 1 proposes a stacked body for a touch panel used as a surface material of a touch panel, and includes a substrate film and at least one layer of a resin cured layer, wherein the substrate film is a polyimide film or an aramid film; and a crack or a fracture does not occur when a test wherein the whole surface of the stacked body for a touch panel is folded into 180° so that the distance between thereof is 3 mm, is carried out repeatedly for 100,000 times.

Also, Patent Document 2, for example, proposes a laminated film including a resin film containing a polyimide-based polymer; and a functional layer provided on at least one principal face side of the resin film, wherein the resin film further contains a silicon material containing silicon atoms.

### CITATION LIST

### Patent Documents

Patent Document 1: Japanese Patent Application Laid-Open (JP-A) No. 2017-33033
Patent Document 2: JP-A No. 2016-93992

### SUMMARY OF DISCLOSURE

### Technical Problem

However, even the stacked body as disclosed in Patent Documents 1 and 2 may not have sufficient bending resistance.

The present disclosure has been made in view of the above circumstances, and an object of the present disclosure is to provide a stacked body for a display device with good bending resistance.

### Solution to Problem

In order to solve the problems, the inventors of the present disclosure have carried out intensive studies, and found out that, in a stacked body including a polyimide substrate, and a functional layer placed on one surface of the polyimide substrate, the bending resistance of the stacked body is greatly influenced by the close adhesiveness between the polyimide substrate and functional layer, and the close adhesiveness between the polyimide substrate and functional layer is decreased by the deterioration of the polyimide substrate or functional layer due to ultraviolet rays. And the inventors of the present disclosure have found out that good bending resistance may be obtained by employing the configuration described later.

One embodiment of the present disclosure provides a stacked body for a display device comprising a polyimide substrate, and a functional layer including an ultraviolet absorber, placed on one surface of the polyimide substrate, wherein a difference of a crack elongation of the stacked body for a display device measured by the following method, before and after the following light resistance test, is 0.6 or less.

Light resistance test: xenon light is irradiated for 60 hours from a functional layer side surface of the stacked body for a display device under conditions of a temperature of 50° C., humidity of 50% RH, wavelength range of 300 nm or more and 400 nm or less, and radiation illuminance of 60 W/m².

Method for measuring crack elongation: using a test piece of a size of 3 mm width and 100 mm length, a tensile length when a crack occurs in the stacked body for a display device is measured under conditions of a temperature of 23±5° C., humidity of 30% RH or more and 70% RH or less, pulling speed of 10 mm/minute, and a distance between grips of 50 mm. The crack elongation is calculated from the following formula (1).

$$Crack elongation ( \% ) = 100 \times tensile length ( mm ) / distance between grips ( mm ) \qquad ( 1 )$$

Another embodiment of the present disclosure provides a stacked body for a display device comprising a polyimide substrate, and a functional layer including an ultraviolet absorber, placed on one surface of the polyimide substrate, wherein a crack elongation of the stacked body for a display device measured by the following method, after the following light resistance test, is 3.0% or more and 6.0% or less.

Light resistance test: xenon light is irradiated for 60 hours from a functional layer side surface of the stacked body for a display device under conditions of a temperature of 50° C., humidity of 50% RH, wavelength range of 300 nm or more and 400 nm or less, and radiation illuminance of 60 W/m².

Method for measuring crack elongation: using a test piece of a size of 3 mm width and 100 mm length, a tensile length when a crack occurs in the stacked body for a display device is measured under conditions of a temperature of 23±5° C., humidity of 30% RH or more and 70% RH or less, pulling speed of 10 mm/minute, and a distance between grips of 50 mm. The crack elongation is calculated from the following formula (1).

$$Crack elongation ( \% ) = 100 \times tensile length ( mm ) / distance between grips ( mm ) \qquad ( 1 )$$

Another embodiment of the present disclosure provides a stacked body for a display device comprising a polyimide substrate, and an ultraviolet absorber-containing hard coating layer including an ultraviolet absorber and resin, placed on one surface of the polyimide substrate, wherein a product of a content (parts by mass) of the ultraviolet absorber with respect to 100 parts by mass of the resin in the ultraviolet absorber-containing hard coating layer; and a thickness (μm) of the ultraviolet absorber-containing hard coating layer is 110 or more and 350 or less.

Another embodiment of the present disclosure provides a stacked body for a display device comprising a polyimide substrate, and an ultraviolet absorber-containing hard coating layer including an ultraviolet absorber and resin, placed on one surface of the polyimide substrate, wherein a product of a ratio, in an infrared absorption spectrum measured by an infrared spectroscopy of the ultraviolet absorber-containing hard coating layer, of a peak strength of a peak deriving from a triazole ring included in the ultraviolet absorber with respect to a peak strength of a peak deriving from a carbonyl bond; and a thickness (μm) of the ultraviolet absorber-containing hard coating layer is 4.1 or more and 10.8 or less.

Another embodiment of the present disclosure provides a stacked body for a display device comprising a hard coating layer, a polyimide substrate, and an ultraviolet absorbing layer including an ultraviolet absorber and resin, in this order, wherein a product of a content (parts by mass) of the ultraviolet absorber with respect to 100 parts by mass of the resin in the ultraviolet absorbing layer; and a thickness (μm) of the ultraviolet absorbing layer is 70 or more and 280 or less.

Another embodiment of the present disclosure provides a stacked body for a display device comprising a hard coating layer, a polyimide substrate, and an ultraviolet absorbing layer including an ultraviolet absorber and resin, in this order, wherein a product of a ratio, in an infrared absorption spectrum measured by an infrared spectroscopy of the ultraviolet absorbing layer, of a peak strength of a peak deriving from a triazole ring included in the ultraviolet absorber with respect to a peak strength of a peak deriving from a carbonyl bond; and a thickness (μm) of the ultraviolet absorbing layer is 2.5 or more and 7.8 or less.

Another embodiment of the present disclosure provides a display device comprising: a display panel, and the stacked body for a display device described above placed on an observer side of the display panel.

### Advantageous Effects of Disclosure

The present disclosure has an effect that a stacked body for a display device with good bending resistance may be provided.

### BRIEF DESCRIPTION OF DRAWINGS

FIG. 1 is a schematic cross-sectional view illustrating an example of a stacked body for a display device in the present disclosure.

FIG. 2 is a schematic view explaining a dynamic bending test.

FIG. 3 is a schematic cross-sectional view illustrating an example of a stacked body for a display device in the present disclosure.

FIG. 4 is a schematic cross-sectional view illustrating an example of a stacked body for a display device in the present disclosure.

FIG. 5 is a schematic cross-sectional view illustrating an example of a stacked body for a display device in the present disclosure.

FIG. 6 is a schematic cross-sectional view illustrating an example of a stacked body for a display device in the present disclosure.

FIG. 7 is a schematic cross-sectional view illustrating an example of a stacked body for a display device in the present disclosure.

FIG. 8 is a schematic cross-sectional view illustrating an example of a display device in the present disclosure.

FIG. 9 is a schematic cross-sectional view illustrating an example of a display device in the present disclosure.

### DESCRIPTION OF EMBODIMENTS

Embodiments in the present disclosure are hereinafter explained with reference to, for example, drawings. However, the present disclosure is enforceable in a variety of different forms, and thus should not be taken as is limited to the contents described in the embodiments exemplified as below. Also, the drawings may show the features of the present disclosure such as width, thickness, and shape of each part schematically comparing to the actual form in order to explain the present disclosure more clearly in some cases; however, it is merely an example, and thus does not limit the interpretation of the present disclosure. Also, in the present descriptions and each drawing, for the factor same as that described in the figure already explained, the same reference sign is indicated and the detailed explanation thereof may be omitted.

In the present descriptions, in expressing an aspect wherein some member is placed on the other member, when described as merely “on” or “below”, unless otherwise stated, it includes both of the following cases: a case wherein some member is placed directly on or directly below the other member so as to be in contact with the other member, and a case wherein some member is placed on the upper side or the lower side of the other member via yet another member. Also, in the present descriptions, on the occasion of expressing an aspect wherein some member is placed on the surface of the other member, when described as merely “on the surface”, unless otherwise stated, it includes both of the following cases: a case wherein some member is placed directly on or directly below the other member so as to be in contact with the other member, and a case wherein some member is placed on the upper side or the lower side of the other member via yet another member.

A stacked body for a display device and a display device in the present disclosure are hereinafter described in detail.

### A. Stacked Body for Display Device

The stacked body for a display device in the present disclosure includes 6 embodiments. Each embodiment is hereinafter described.

### I. First Embodiment

The first embodiment of the stacked body for a display device in the present disclosure comprises a polyimide substrate, and a functional layer including an ultraviolet absorber, placed on one surface of the polyimide substrate, wherein a difference of a crack elongation of the stacked body for a display device measured by the following method, before and after the following light resistance test, is 0.6 or less.

Light resistance test: xenon light is irradiated for 60 hours from a functional layer side surface of the stacked body for a display device under conditions of a temperature of 50° C., humidity of 50% RH, wavelength range of 300 nm or more and 400 nm or less, and radiation illuminance of 60 W/m²

Method for measuring crack elongation: using a test piece of a size of 3 mm width and 100 mm length, a tensile length when a crack occurs in the stacked body for a display device is measured under conditions of a temperature of 23±5° C., humidity of 30% RH or more and 70% RH or less, pulling speed of 10 mm/minute, and a distance between grips of 50 mm. The crack elongation is calculated from the following formula (1).

$$Crack elongation ( \% ) = 100 \times tensile length ( mm ) / distance between grips ( mm ) \qquad ( 1 )$$

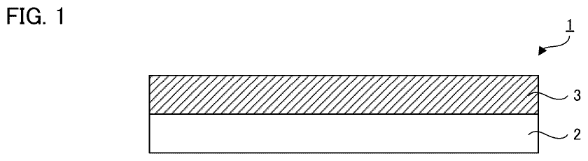

FIG. 1 is a schematic cross-sectional view illustrating an example of a stacked body for a display device in the present embodiment. As shown in FIG. 1, a stacked body for a display device 1 comprises a polyimide substrate 2, and a functional layer 3 including an ultraviolet absorber, placed on one surface of the polyimide substrate 2. Also, in the stacked body for a display device 1, a difference of a crack elongation of the stacked body for a display device 1 measured by the method described above, before and after the light resistance test described above, is a predetermined value or less.

In the present embodiment, by the functional layer including the ultraviolet absorber, and further, by selecting the functional layer so that the difference of the crack elongation before and after the light resistance test, is a predetermined value or less, specifically, by adjusting the content of the ultraviolet absorber in the functional layer and the thickness of the functional layer, for example, the deterioration of the polyimide substrate or functional layer due to ultraviolet rays may be suppressed, and the decreased in the close adhesiveness between the polyimide substrate and functional layer, due to thereof, may be suppressed. As the result, the decrease in bending resistance due to the decrease in close adhesiveness between the polyimide substrate and functional layer may be suppressed, and good bending resistance may be obtained. Also, since the functional layer includes an ultraviolet absorber, ultraviolet deterioration of the polyimide substrate may be suppressed; the color change of the polyimide substrate over time may be suppressed; and a stacked body for a display device with good transparency may be obtained.

Each constitution of the stacked body for a display device in the present embodiment is hereinafter described.

### 1. Properties of Stacked Body for Display Device

### (1) Crack Elongation

In the stacked body for a display device in the present embodiment, the difference of the crack elongation of the stacked body for a display device measured by a predetermined method, before and after a predetermined light resistance test is 0.6 or less, preferably 0.4 or less, and more preferably 0.2 or less. Since the difference of the crack elongation before and after the light resistance test is in the above range, the decreased in the close adhesiveness between the polyimide substrate and functional layer due to ultraviolet ray deterioration of the polyimide substrate and functional layer may be suppressed, and good bending resistance may be obtained. The lower the difference of the crack elongation before and after the light resistance test, the better, so that the lower limit is not particularly limited; and for example, the lower limit may be 0.05 or more. The difference of the crack elongation before and after the light resistance test is preferably 0.05 or more and 0.6 or less, more preferably 0.05 or more and 0.4 or less, and further preferably 0.05 or more and 0.2 or less.

Here, in the light resistance test, xenon light is irradiated for 60 hours from a functional layer side surface of the stacked body for a display device under conditions of a temperature of 50° C., humidity of 50% RH, wavelength range of 300 nm or more and 400 nm or less, and radiation illuminance of 60 W/m².

Also, the crack elongation is measured by the following method. Firstly, the stacked body for a display device is cut into a size of 3 mm width×100 mm length to prepare a test piece. Then, using a tensile tester, the test is carried out under conditions of a temperature of 23±5° C., humidity of 30% RH or more and 70% RH or less, pulling speed of 10 mm/minute, and a distance between grips of 50 mm. The stacked body for a display device is pulled until a crack occurs, and the tensile length at the time the crack occurred in the stacked body for a display device is measured. Incidentally, the presence of the crack in the stacked body for a display device is determined visually by irradiating the test piece with an LED. The crack elongation is calculated from the following formula (1).

$$Crack elongation ( \% ) = 100 \times tensile length ( mm ) / distance between grips ( mm ) \qquad ( 1 )$$

Then, the difference of the crack elongation before and after the light resistance test is determined from the following formula (2).

$$Difference of crack elongation before and after light resistance test = crack elongation before light resistance test ( \% ) - crack elongation after light resistance test ( \% ) \qquad ( 2 )$$

Examples of a method for reducing the difference of crack elongation before and after the light resistance test may include, as described later, a method wherein the content of the ultraviolet absorber in the functional layer, or the thickness of the functional layer is adjusted.

In general, in the resin layer, the crack elongation tends to decrease due to ultraviolet ray deterioration. In the stacked body for a display device in the present embodiment, the crack elongation of the stacked body for a display device measured by a predetermined method, after a predetermined light resistance test is preferably, for example, 3.0% or more, more preferably 3.7% or more, and further preferably 4.0% or more. When the crack elongation after the light resistance test is in the above range, the difference of the crack elongation before and after the light resistance test may be reduced. Thereby, the decrease in the close adhesiveness between the polyimide substrate and functional layer due to ultraviolet ray deterioration of the polyimide substrate and functional layer may be suppressed, and good bending resistance may be obtained. Also, the crack elongation after the light resistance test is, for example, 6.0% or less, and may be 5.0% or less. The crack elongation after the light resistance test is preferably, for example, 3.0% or more and 6.0% or less, may be 3.7% or more and 5.0% or less, and may be 4.0% or more and 5.0% or less.

Incidentally, the method for measuring a crack elongation after the light resistance test is as described above.

### (2) Yellowness

In the stacked body for a display device in the present embodiment, the yellowness is preferably, for example, 15.0 or less, more preferably 10.0 or less, further preferably 9.5 or less, and particularly preferably 8.5 or less. When the yellowness is low as in the above range, the yellowing may be suppressed and the transparency may be improved. Also, the yellowness is, for example, preferably 5.0 or more, more preferably 6.0 or more, and further preferably 6.5 or more. As will be discussed later, the ultraviolet absorber preferably absorbs ultraviolet rays in the UVA region having long wavelengths among ultraviolet rays, and such ultraviolet absorber also absorbs visible rays. Therefore, in the stacked body for a display device including a functional layer including such the ultraviolet absorber, the yellowness tends to be high. When the yellowness is in the above range, it can be said that the functional layer includes the preferable ultraviolet absorber as described above. The yellowness of the stacked body for a display device is preferably, for example, 5.0 or more and 15.0 or less, more preferably 5.0 or more and 10.0 or less, further preferably 6.0 or more and 9.5 or less, particularly preferably 6.5 or more and 8.5 or less.

Incidentally, the yellowness is the yellowness before the light resistance test described above. Here, the yellowness (YI) may be determined according to JIS K7373:2006. Specifically, based on the transmittance measured using an ultraviolet-visible and near-infrared spectrophotometer by a spectrophotometric colorimetry; using a deuterium lamp and a tungsten halogen lamp; with 0.5 nm interval in the range of 300 nm or more and 780 nm or less; in conditions of a viewing angle of 2 degrees, and standard light C, the tristimulus values X, Y and Z in the XYZ color system are determined, and the yellowness may be calculated from the following formula (3), from the values of X, Y, and Z.

$$YI = 100 ( 1.27 \; 69 X - 1.0592 Z ) / Y \qquad ( 3 )$$

The following conditions may be used for measuring the yellowness (YI).

### (Measurement Conditions)

Viewing angle: 2°
Illuminant: C
Light source: deuterium lamp and tungsten halogen lamp
Wavelength range: 0.5 nm interval in the range of 300 nm or more and 780 nm or less
Scan speed: high speed
Slit width: 5.0 nm
S/R switch: standard.
Auto Zero: carried out at 550 nm after baseline scan

As the ultraviolet-visible and near-infrared spectrophotometer, for example, “V-7100” from JASCO Corporation may be used.

### (3) Total Light Transmittance

The total light transmittance of the stacked body for a display device in the present embodiment is preferably, for example, 85% or more, more preferably 88% or more, and further preferably 90% or more. When the total light transmittance is high as described above, the stacked body for a display device may have good transparency.

Here, the total light transmittance of the stacked body for a display device may be measured according to JIS K7361-1:1999, and may be measure with, for example, a haze meter HM150 from Murakami Color Research Laboratory Co., Ltd.

### (4) Haze

The haze of the stacked body for a display device in the present embodiment is preferably, for example, 5% or less, more preferably 2% or less, and further preferably 1% or less. When the haze is low as described above, the stacked body for a display device may have good transparency.

Here, the haze of the stacked body for a display device may be measured according to JIS K-7136:2000, and may be measure with, for example, a haze meter HM150 from Murakami Color Research Laboratory Co., Ltd.

### (5) Bending Resistance

The stacked body for a display device in the present embodiment preferably has a bending resistance. Specifically, when the dynamic bending test described below is carried out to the stacked body for a display device, it is preferable that a crack or a fracture does not occur in the stacked body for a display device.

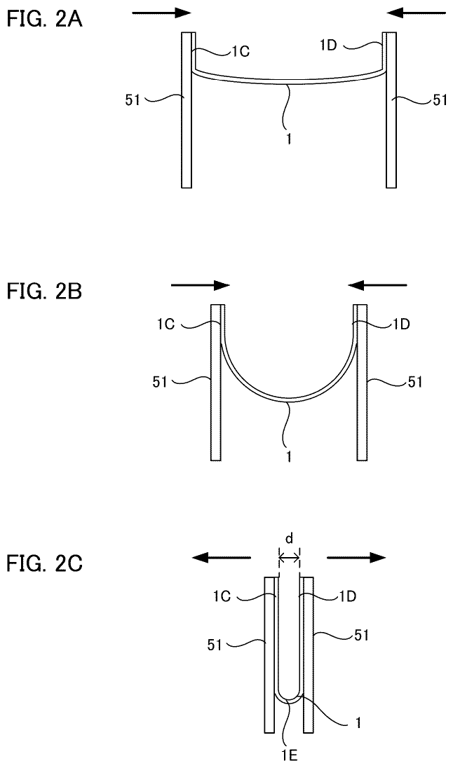

The dynamic bending test is carried out as follows. Firstly, a stacked body for a display device having a size of 20 mm×100 mm is prepared. Then, in the dynamic bending test, as shown in FIG. 2A, short side portion 1C and short side portion 1D opposing to the short side portion 1C of the stacked body for a display device 1 are respectively fixed by parallelly arranged fixing portions 51. Also, as shown in FIG. 2A, the fixing portions 51 are movable by sliding in horizontal direction. Then, as shown in FIG. 2B, by moving the fixing portions 51 so as to be closer to each other, the stacked body for a display device 1 is deformed so as to be folded. Further, as shown in FIG. 2C, after moving the fixing portions 51 to the position wherein distance “d” between the two opposing short side portions 1C and 1D of the stacked body for a display device 1 fixed by the fixing portions 51 is a predetermined value, the deformation of the stacked body for a display device 1 is dissolved by moving the fixing portions 51 in opposite directions. As shown in FIGS. 2A to 2C, by moving the fixing portions 51, the stacked body for a display device 1 may be folded into 180°. Also, by carrying out the dynamic bending test so that bent portion 1E of the stacked body for a display device 1 does not protrude from the lower end edge of the fixing portions 51, and by controlling the distance when the fixing portions 51 are the closest, distance “d” between the two opposing short side portions 1C and 1D of the stacked body for a display device 1 may be a predetermined value. For example, when the distance “d” between the short side portions 1C and 1D is 10 mm, the outer diameter of the bent portion 1E is regarded as 10 mm. For dynamic bending testing, for example, a durability tester (product name “DLDMLH-FS” from Yuasa Co., Ltd.) may be used.

In the stacked body for a display device, it is preferable that a crack or a fracture does not occur when the dynamic bending test wherein the stacked body for a display device 1 is folded into 180° so that the distance “d” between the opposing short side portions 1C and 1D of the stacked body for a display device 1 is 8 mm, is carried out repeatedly for 200,000 times. Among the above, it is preferable that a crack or a fracture does not occur when the dynamic bending test wherein the stacked body for a display device 1 is folded into 180° so that the distance “d” between the opposing short side portions 1C and 1D of the stacked body for a display device 1 is 6 mm, is carried out repeatedly for 200,000 times. Particularly, it is preferable that a crack or a fracture does not occur when the dynamic bending test wherein the stacked body for a display device 1 is folded into 180° so that the distance “d” between the opposing short side portions 1C and 1D of the stacked body for a display device 1 is 4 mm, is carried out repeatedly for 200,000 times.

In the dynamic bending test, the stacked body for a display device may be folded so that the functional layer is on the outer side, or the stacked body for a display device may be folded so that the functional layer is on the inner side; and in either of these cases, it is preferable that a crack or a fracture does not occur in the stacked body for a display device.

### 2. Functional Layer

The functional layer in the present embodiment is a member placed on one surface of the polyimide substrate, and including ultraviolet absorber.

### (1) Material of Functional Layer

The functional layer in the present embodiment may include an ultraviolet absorber and resin.

### (a) Ultraviolet Absorber

In the functional layer in the present embodiment, the ultraviolet absorber is selected so that the difference of the crack elongation before and after the light resistance test is a predetermined value or less, and an appropriate amount is included in the functional layer.

The ultraviolet absorber preferably absorbs ultraviolet rays in the UVA region having long wavelengths among ultraviolet rays. Specifically, in the ultraviolet absorber, the peak of the absorption wavelength, in absorption measurement preferably exist in 300 nm or more and 390 nm or less, more preferably 320 nm or more and 370 nm or less, and further preferably 330 nm or more and 370 nm or less. Such an ultraviolet absorber is able to effectively absorb ultraviolet rays in the UVA region and is able to effectively suppress ultraviolet ray deterioration of the polyimide substrate and functional layer. Also, as described later, when the functional layer has hard coating properties, and when a polymerization initiator is used, by shifting the peak wavelength of the ultraviolet absorber from the absorption wavelength of the polymerization initiator (for example, 250 nm), a functional layer with ultraviolet ray absorbing ability may be formed without causing curing inhibition of the functional layer.

Among them, from the viewpoint of suppressing the coloring due to the ultraviolet absorber, the peak of the absorption wavelength of the ultraviolet absorber is preferably 380 nm or less.

Incidentally, the absorption of the ultraviolet absorber may be measured using, for example, an ultraviolet-visible-near infrared spectrophotometer (such as V-7100 from JASCO Corporation).

Examples of the ultraviolet absorber may include triazine based ultraviolet absorbers; benzophenone based ultraviolet absorbers such as hydroxybenzophenone based ultraviolet absorbers; and benzotriazole based ultraviolet absorbers.

Among them, from the viewpoint of suppressing the ultraviolet ray deterioration of the polyimide substrate and functional layer, one kind or more of the ultraviolet absorber selected from the group consisting of a hydroxybenzophenone based ultraviolet absorber and a benzotriazole based ultraviolet absorber is preferable, and one kind or more of the ultraviolet absorber selected from the group consisting of a hydroxybenzophenone based ultraviolet absorber is more preferable.

Hydroxybenzophenone based ultraviolet absorber refers to an ultraviolet absorber with a benzophenone skeleton substituted with a hydroxy group. Specific examples thereof may include 2-hydroxybenzophenone, 4-hydroxybenzophenone, 2-hydroxy-4-methoxybenzophenone, 2-hydroxy-4-octyloxybenzophenone, 2-hydroxy-4-dodecyloxybenzophenone, 2-hydroxy-4-benziloxybenzophenone, 2,4-dihydroxybenzophenone, 2-hydroxy-4-methoxy-4′-chlorobenzophenone, 2,2′-dihydroxy-4-methoxybenzophenone, 2,2′-dihydroxy-4,4′-dimethoxybenzophenone, 2,2′,4,4′-tetrahydroxybenzophenone, 2,2′-dihydroxy-4,4′-diallyloxybenzophenone, 2,2′-dihydroxy-4,4′-diallylbenzophenone, 2,4-dihydroxy-4-methoxy-5-sulfobenzophenone, and 2-hydroxy-4-methoxybenzophenone-5-sulfonic acid hydrate. The hydroxybenzophenone based ultraviolet absorber may be one kind only, and may be two kinds or more.

Among the hydroxybenzophenone based ultraviolet absorber, 2-hydroxybenzophenone based ultraviolet absorber is preferable, one kind or more selected from the group consisting of a hydroxybenzophenone based ultraviolet absorber having the following general formula (A) is more preferable. The ultraviolet ray deterioration of the polyimide substrate and functional layer may be suppressed, and durability may be improved.

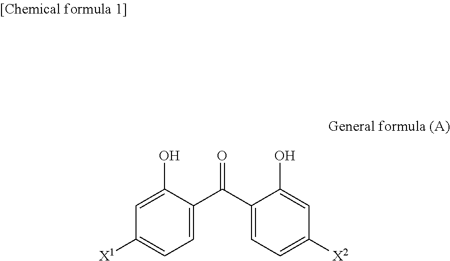

(In the general formula (A), X¹ and X² each independently represents a hydroxyl group, —OR^{a}, or a 1-15C hydrocarbon group; R^{a} represents a 1-15C hydrocarbon group.)

In the general formula (A), examples of the 1-15C hydrocarbon group in X¹, X², and R^{a} may include a methyl group, an ethyl group, a propyl group, a butyl group, a pentyl group, a hexyl group, a heptyl group, an octyl group, a dodecyl group, an allyl group, and a benzyl group. The 3C or more aliphatic hydrocarbon group may be a straight chain, or a branched respectively. The hydrocarbon group is preferably 1-12C, and more preferably 1-8C. From the viewpoint of easily improved transparency, the hydrocarbon group is preferably an aliphatic hydrocarbon group, among them, preferably a methyl group or an allyl group.

From the viewpoint of improving the durability, X¹ and X² each independently is preferably a hydroxyl group, or —OR^{a}.

Among them, one kind or more selected from the group consisting of the benzophenone based ultraviolet absorber having the general formula (A) is preferably one kind or more selected from the group consisting of 2,2′,4,4′-tetrahydroxy benzophenone, 2,2′-dihydroxy4,4′-dimethoxybenzophenone, and 2,2′-dihydroxy-4,4′-diallyloxybenzophenone; more preferably one kind or more selected from the group consisting of 2,2′,4,4′-tetrahydroxy benzophenone, and 2,2′-dihydroxy-4,4′-dimethoxybenzophenone.

Examples of the benzotriazole based ultraviolet absorber may include sesamol-type benzotriazole based monomers, 2-[2-hydroxy-3,5-bis(α,α-dimethylbenzyl)phenyl]-2H-benzotriazole (“TINUVIN 326” from BASF SE). Among them, sesamol-type benzotriazole based monomers are preferable for their large spectral slope and they are able to absorb ultraviolet rays more selectively.

The sesamol-type benzotriazole based monomer is not particularly limited, and examples thereof may include 2-[2-(6-hydroxybenzo[1,3]dioxole-5-yl)-2H-benzotriazole-5-ylethylmethacrylate, 2-[2-(6-hydroxybenzo[1,3]-dioxole-5-yl)-2H-benzotriazole-5-yl]propylmethacrylate, 3-[2-(6-hydroxybenzo[1,3]-dioxole-5-yl)-2H-benzotriazole-5-yl]propylacrylate, 4-[2-(6-hydroxybenzo[1,3]-dioxole-5-yl)-2H-benzotriazole-5-yl]butylmethacrylate, 4-[2-(6-hydroxybenzo[1,3]-dioxole-5-yl)]-2H-benzotriazole-5-yl]butylacrylate, 2-[2-(6-hydroxybenzo[1,3]-dioxole-5-yl)-2H-benzotriazole-5-yloxy]ethylmethacrylate, 2-[2-(6-hydroxybenzo[1,3]dioxole-5-yl)-2H-benzotriazole-5-yloxy]ethylacrylate, 2-[3-{2-(6-hydroxybenzo[1,3]dioxole-5-yl)-2H-benzotriazole-5-yl)-2H-benzotriazole-5-yl}propanoyloxy]ethylmethacrylate, 2-[3-{2-}(6-hydroxybenzo[1,3]dioxole-5-yl)-2H-benzotriazole-5-yl]-2H-benzotriazole-5-yl}propanoyloxy]ethylacrylate, 4-[3-{2-(6-hydroxybenzo[1,3]dioxole-5-yl)-2H-benzotriazole-5-yl}propanoyloxy]butylmethacrylate, 4-[3-{2-(6-hydroxybenzo[1,3]dioxole-5-yl)-2H-benzotriazole-5-yl}propanoyloxy]butylacrylate, 2-[3-{2-(6-hydroxybenzo[1,3]dioxole-5-yl)-2H-benzotriazole-5-yl}propanoyloxy]ethylmethacrylate, 2-[3-{2-(6-hydroxybenzo[1,3]dioxole-5-yl)-2H-benzotriazole-5-yl}propanoyloxy]ethylacrylate, 2-(methacryloyloxy)ethyl2-(6-hydroxybenzo[1,3]dioxole-5-yl)-2H-benzotriazole-5-carboxylate, 4-(methacryloyloxy)butyl2-(6-hydroxybenzo[1,3]dioxol-5-yl)-2H-benzotriazole-5-carboxylate, 4-(methacryloyloxy)butyl2-(6-hydroxybenzo[1,3]dioxol-5-yl)-2H-benzotriazole-5-carboxylate, and 4-(acryloyloxy)butyl2-(6-hydroxybenzo[1,3]dioxol-5-yl)-2H-benzotriazole-5-carboxylate. Also, one type of these sesamol-type benzotriazole based monomers may be used alone, and two types or more of these may be used.

Also, the ultraviolet absorber is preferably a polymer or oligomer. This is because the bleed-out of the ultraviolet absorber, when the stacked body for a display device is bent repeatedly, may be suppressed. Examples of such ultraviolet absorber may include polymers or oligomers including a triazine skeleton, a benzophenone skeleton, or a benzotriazole skeleton. Specifically, it is preferably ones obtained by thermally copolymerizing methyl methacrylate (MMA), and (meth)acrylate including a benzotriazole skeleton or a benzophenone skeleton, at an arbitrary ratio.

The content of the ultraviolet absorber in the functional layer is not particularly limited, as long as it is a content capable of obtaining a stacked body for a display device satisfying the difference of the crack elongation before and after the light resistance test, and it is appropriately selected according to the thickness of the functional layer, or the function of the functional layer.

For example, when the thickness of the functional layer is relatively thick, specifically, when the thickness of the functional layer is 6 μm or more and 50 μm or less, the content of the ultraviolet absorber in the functional layer is preferably 15 parts by mass or more and 30 parts by mass or less, more preferably 15 part by mass or more and 25 parts by mass or less, and further preferably 20 parts by mass or more and 25 parts by mass or less, with respect to 100 parts by mass of the resin. Also, when the thickness of the functional layer is relatively thin, specifically, when the thickness of the functional layer is 0.5 μm or more and less than 6 μm, the content of the ultraviolet absorber in the functional layer is preferably 25 parts by mass or more and 50 parts by mass or less, more preferably 35 part by mass or more and 50 parts by mass or less, and further preferably 40 parts by mass or more and 50 parts by mass or less, with respect to 100 parts by mass of the resin. When the content of the ultraviolet absorber in the functional layer is too low, the effect of suppressing the ultraviolet ray deterioration of the polyimide substrate or functional layer, may not be obtained sufficiently. Also, when the content of the ultraviolet absorber in the functional layer is too high, since the functional layer may not be sufficiently cured, the close adhesiveness between the functional layer and the polyimide substrate may be decreased so that the bending resistance may be decreased; or coloring such as yellowing of the functional layer may occur depending on the type of the ultraviolet absorber, and the transparency of the stacked body for a display device may be decreased. In particular, when the thickness of the functional layer is relatively thin, the content of the ultraviolet absorber in the functional layer is necessary to be relatively high in order to suppress the ultraviolet ray deterioration of the polyimide substrate or functional layer. Therefore, from the viewpoint of the bending resistance, and in order to suppress the ultraviolet ray deterioration of the polyimide substrate or functional layer, the content of the ultraviolet absorber in the functional layer is preferably in the above range.

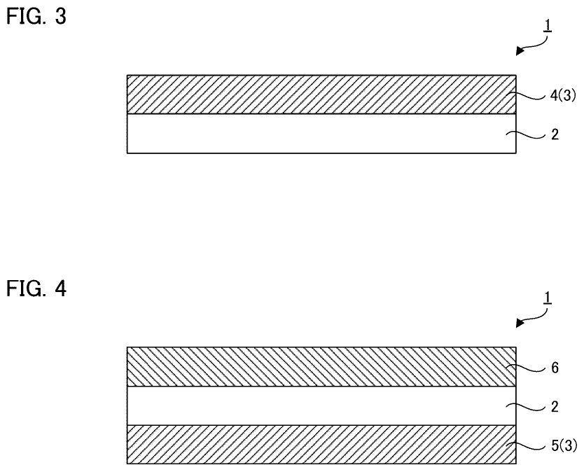

Also, when the functional layer 3 is an ultraviolet absorber-containing hard coating layer 4 including an ultraviolet absorber and resin as shown in FIG. 3 for example, the content of the ultraviolet absorber in the ultraviolet absorber-containing hard coating layer is preferably 15 parts by mass or more and 30 parts by mass or less, more preferably 15 part by mass or more and 25 parts by mass or less, and further preferably 20 parts by mass or more and 25 parts by mass or less, with respect to 100 parts by mass of the resin. When the content of the ultraviolet absorber in the ultraviolet absorber-containing hard coating layer is too low, the effect of suppressing the ultraviolet ray deterioration of the polyimide substrate or ultraviolet absorber-containing hard coating layer may not be obtained sufficiently. Also, when the content of the ultraviolet absorber in the ultraviolet absorber-containing hard coating layer is too high, since the ultraviolet absorber-containing hard coating layer may not be sufficiently cured, the close adhesiveness between the ultraviolet absorber-containing hard coating layer and the polyimide substrate may be decreased so that the bending resistance may be decreased; or coloring such as yellowing of the ultraviolet absorber-containing hard coating layer may occur depending on the type of the ultraviolet absorber, and the transparency of the stacked body for a display device may be decreased.

Also, when the functional layer 3 is an ultraviolet absorbing layer 5 including an ultraviolet absorber and resin, when the stacked body for a display device 1 includes an ultraviolet absorbing layer 5 (functional layer 3), a polyimide substrate 2, and a hard coating layer 6 in this order as shown in FIG. 4 for example, the content of the ultraviolet absorber in the ultraviolet absorbing layer is preferably 25 parts by mass or more and 50 parts by mass or less, more preferably 35 part by mass or more and 50 parts by mass or less, and further preferably 40 parts by mass or more and 50 parts by mass or less, with respect to 100 parts by mass of the resin. When the content of the ultraviolet absorber in the ultraviolet absorbing layer is too low, the effect of suppressing the ultraviolet ray deterioration of the polyimide substrate or hard coating layer, may not be obtained sufficiently. Also, when the content of the ultraviolet absorber in the ultraviolet absorbing layer is too high, since the ultraviolet absorbing layer may not be sufficiently cured, the close adhesiveness between the ultraviolet absorbing layer and the polyimide substrate may be decreased so that the bending resistance may be decreased; or coloring such as yellowing of the ultraviolet absorbing layer may occur depending on the type of the ultraviolet absorber, and the transparency of the stacked body for a display device may be decreased.

Also, when the functional layer is an ultraviolet absorber-containing hard coating layer including the ultraviolet absorber and resin, in the ultraviolet absorber-containing hard coating layer, when a secondary ion intensity of the ultraviolet absorber-containing hard coating layer in a depth direction is measured by a time-of-flight secondary ion mass spectrometry, a ratio of a secondary ion intensity, deriving from the ultraviolet absorber, at a depth of 1 μm from a surface of the ultraviolet absorber-containing hard coating layer, on opposite side to the polyimide substrate; with respect to a secondary ion intensity, deriving from the ultraviolet absorber, at a depth of 1 μm from a polyimide substrate side surface of the ultraviolet absorber-containing hard coating layer, is preferably, for example, 0.7 or more and 1.5 or less, may be 0.8 or more and 1.3 or less, and may be 0.9 or more and 1.2 or less. When the ratio of a secondary ion intensity deriving from the ultraviolet absorber is closer to 1.0, the ultraviolet absorber in the ultraviolet absorber-containing hard coating layer is not unevenly distributed, it can be said that the ultraviolet absorber is evenly distributed. Therefore, when the ratio of a secondary ion intensity deriving from the ultraviolet absorber is in the above range, the ultraviolet absorber is evenly dispersed in the ultraviolet absorber-containing hard coating layer. Thereby, the hardness of the ultraviolet absorber-containing hard coating layer may be made even so that the surface hardness and abrasion resistance may be increased.

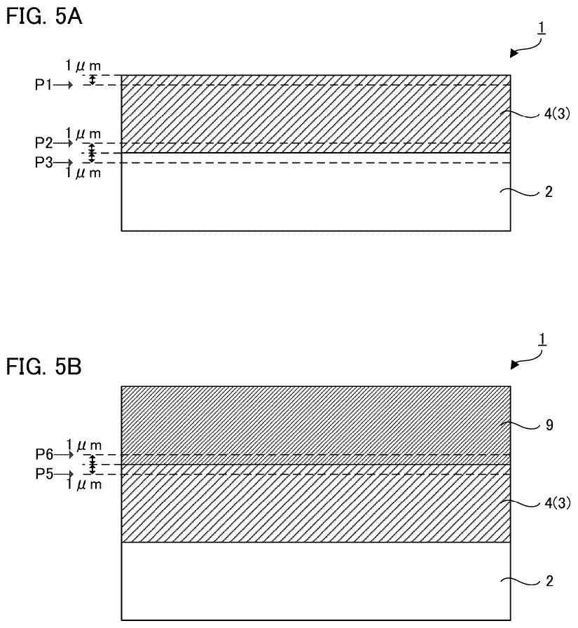

Incidentally, in FIG. 5A for example, the position at a depth of 1 μm from the surface of the ultraviolet absorber-containing hard coating layer 4, on opposite side to the polyimide substrate 2 is the position P1, and the position at a depth of 1 μm from the polyimide substrate 2 side surface of the ultraviolet absorber-containing hard coating layer 4 is the position P2.

Examples of a way to make the ratio of the secondary ion intensity, deriving from the ultraviolet absorber, in a predetermined range may include an improvement of the compatibility between the resin and ultraviolet absorber. It is thought that, when the compatibility between the resin and the ultraviolet absorber is good, the ultraviolet absorber is likely to be dispersed evenly in the ultraviolet absorber-containing hard coating layer so that the ratio of the secondary ion intensity, deriving from the ultraviolet absorber, is likely to be in the predetermined range.

Also, when the functional layer is an ultraviolet absorber-containing hard coating layer including the ultraviolet absorber and resin, in the ultraviolet absorber-containing hard coating layer and the polyimide substrate, when a secondary ion intensity of the ultraviolet absorber-containing hard coating layer and the polyimide substrate in a depth direction is measured by a time-of-flight secondary ion mass spectrometry, a ratio of a secondary ion intensity, deriving from the ultraviolet absorber, at a depth of 1 μm from an ultraviolet absorber-containing hard coating layer side surface of the polyimide substrate; with respect to a secondary ion intensity, deriving from the ultraviolet absorber, at a depth of 1 μm from a polyimide substrate side surface of the ultraviolet absorber-containing hard coating layer, is preferably, for example, 0.1 or less, more preferably 0.07 or less, and may be 0.05 or less. When the ratio of the secondary ion intensity, deriving from the ultraviolet absorber is in the above range, almost no ultraviolet absorber is included in the polyimide substrate. Therefore, the migration of the ultraviolet absorber in the ultraviolet absorber-containing hard coating layer into the polyimide substrate may be suppressed. Thereby, the decrease in the polyimide substrate performance, due to the migration of the ultraviolet absorber, may be suppressed.

Incidentally, in FIG. 5A for example, the position at a depth of 1 μm from the polyimide substrate 2 side surface of the ultraviolet absorber-containing hard coating layer 4 is the position P2, and the position at a depth of 1 μm from the ultraviolet absorber-containing hard coating layer 4 side surface of the polyimide substrate 2 is the position P3.

Examples of a method to make the ratio of the secondary ion intensity, deriving from the ultraviolet absorber, in a predetermined range may include a method wherein, in the resin composition for an ultraviolet absorber-containing hard coating layer, the content of a solvent having high permeability into the polyimide substrate, and the content of a resin having high permeability into the polyimide substrate are suppressed.

Also, when the functional layer is an ultraviolet absorber-containing hard coating layer including the ultraviolet absorber and resin, and when the stacked body for a display device 1 includes a second hard coating layer 9, an ultraviolet absorber-containing hard coating layer 4 (functional layer 3), and a polyimide substrate 2 in this order as shown in FIG. 5B for example, in the second hard coating layer and ultraviolet absorber-containing hard coating layer, when a secondary ion intensity of the second hard coating layer and ultraviolet absorber-containing hard coating layer in a depth direction is measured by a time-of-flight secondary ion mass spectrometry, the ratio of the secondary ion intensity, deriving from the ultraviolet absorber, at a depth of 1 μm from the ultraviolet absorber-containing hard coating layer side surface of the second hard coating layer; with respect to the secondary ion intensity, deriving from the ultraviolet absorber, at a depth of 1 μm from the second hard coating layer side surface of the ultraviolet absorber-containing hard coating layer, is preferably, for example, 0.1 or less, more preferably 0.07 or less, and may be 0.05 or less. When the ratio of the secondary ion intensity, deriving from the ultraviolet absorber is in the above range, almost no ultraviolet absorber is included in the second hard coating layer. Therefore, the migration of the ultraviolet absorber in the ultraviolet absorber-containing hard coating layer into the second hard coating layer may be suppressed. Thereby, the decrease in the surface hardness and the chafing resistance of the second hard coating layer, due to the migration of the ultraviolet absorber, may be suppressed.

Incidentally, in FIG. 5B for example, the position at a depth of 1 μm from the second hard coating layer 9 side surface of the ultraviolet absorber-containing hard coating layer 4 is the position P5, and the position at a depth of 1 μm from the ultraviolet absorber-containing hard coating layer 4 side surface of the second hard coating layer 9 is the position P6.

Examples of a method to make the ratio of the secondary ion intensity, deriving from the ultraviolet absorber, in a predetermined range may include a method wherein the ultraviolet absorber-containing hard coating layer is appropriately cured; and a method wherein, in the resin composition for a second hard coating layer, a solvent or resin having low permeability into the ultraviolet absorber-containing hard coating layer is selected.

The secondary ion intensity may be measured by a time-of-flight secondary ion mass spectrometry (TOF-SIMS). Specifically, the stacked body for a display device cut out into a size of 10 mm×10 mm is firstly placed in the sample room of a time-of-flight secondary ion mass spectrometer so that the primary ions are irradiated to the surface of the ultraviolet absorber-containing hard coating layer. The primary ions are then irradiated on the surface of the ultraviolet absorber-containing hard coating layer to measure the secondary ion intensity, deriving from the ultraviolet absorber at a predetermined depth. Incidentally, when the second hard coating layer, the ultraviolet absorber-containing hard coating layer, and the polyimide substrate are placed in order, the primary ions are irradiated on the surface of the hard coating layer.

In this case, for example, when the ultraviolet absorber includes a nitrogen atom, CN⁻ is detected as the secondary ion deriving from the ultraviolet absorber. Examples of the ultraviolet absorber including a nitrogen atom may include triazine based ultraviolet absorbers and benzotriazole based ultraviolet absorbers. Also, for example, when the ultraviolet absorber is a benzotriazole based ultraviolet absorber, CN⁻ or C₆H₄N₃⁻ is detected as the secondary ion deriving from the ultraviolet absorber. Also, for example, when the ultraviolet absorber is a benzophenone based ultraviolet absorber, C₁₃H₇O₃⁻ is detected as the secondary ion deriving from the ultraviolet absorber.

As the time-of-flight secondary ion mass spectrometer, for example, “TOF. SIMS5” from IONTOF GmbH may be used. The measurement conditions are shown below. Incidentally, in the following measurement conditions, an AR gas cluster ion beam is used as the etching ion. By using the AR gas cluster ion beam, etching of organic structures with low damage may be carried out.

### (Measurement Conditions)

Secondary ion polarity: negative
Mass range (m/z): 0 to 1500
Raster size: 300 μm
Number of scans: 1 scan/cycle
Number of pixels (per side): 128 pixels
Degree of measurement vacuum (before sample introduction): 4×10⁻⁷ Pa or less
Charging neutralization: Yes
Post-stage acceleration: 9.5 kV
Primary ion: Bi₃⁺⁺
Primary ion acceleration voltage: 25 kV
Pulse width: 16.0 ns
Bunching: Yes (high mass resolution measurement)
Etching ion: AR gas cluster ion beam (Ar-GCIB)
Etching ion acceleration voltage: 20 kV

### (b) Resin

The functional layer in the present embodiment may or may not have, for example, hard coating properties.

Here, “a functional layer having hard coating properties” is a layer configured to improve the surface hardness. Specifically, in the functional layer side surface of the stacked body for a display device, it is referred to as one having a hardness of “H” or more in the pencil hardness test according to JIS K 5600 May 4:1999.

When the functional layer has hard coating properties, examples of the resin may include a cured product of a polymerizable compound. The cured product of a polymerizable compound may be obtained by carrying out a polymerization reaction of a polymerizable compound, by a known method using a polymerization initiator according to the needs.

The polymerizable compound includes at least one polymerizable functional group in the molecule. As the polymerizable compound, for example, at least one kind of radical polymerizable compound and cation polymerizable compound may be used.

The radical polymerizable compound is a compound including a radical polymerizable group. The radical polymerizable group included in the radical polymerizable compound may be any functional group capable of generating a radical polymerization reaction, and is not particularly limited; and examples thereof may include a group including a carbon-carbon unsaturated double bond, and specific examples thereof may include a vinyl group and a (meth) acryloyl group. Incidentally, when the radical polymerizable compound includes two or more radical polymerizable groups, these radical polymerizable groups may be the same, and may be different from each other.

The number of radical polymerizable groups included in one molecule of the radical polymerizable compound is preferably two or more, and more preferably three or more, from the viewpoint of increasing the surface hardness of the functional layer so that the chafing resistance is improved.

Among the above, from the viewpoint of high reactivity, the radical polymerizable compound is preferably a compound including a (meth) acryloyl group. For example, a polyfunctional (meth) acrylate monomer and oligomer having a molecular weight of several hundred to several thousand, and including several (meth) acryloyl groups in the molecule may be preferably used; such as those referred to as urethane (meth)acrylate, polyester (meth)acrylate, epoxy (meth)acrylate, melamine (meth)acrylate, polyfluoroalkyl (meth)acrylate, and silicone (meth)acrylate; and a polyfunctional (meth)acrylate polymer including two or more (meth) acryloyl groups on the side chain of an acrylate polymer may also be preferably used. Among the above, a polyfunctional (meth)acrylate monomer including two or more (meth) acryloyl groups in one molecule may be preferably used. By the functional layer including a cured product of the polyfunctional (meth)acrylate monomer, the surface hardness of the functional layer may be increased so that the chafing resistance may be improved. Further, the close adhesiveness may also be improved. Also, a polyfunctional (meth) acrylate oligomer or polymer including two or more (meth) acryloyl groups in one molecule may also be preferably used. By the functional layer including a cured product of the polyfunctional (meth) acrylate oligomer or polymer, the surface hardness of the functional layer may be increased so that the chafing resistance may be improved. Further, the bending resistance and close adhesiveness may also be improved.

Incidentally, in the present specification, (meth) acryloyl represents each of acryloyl and methacryloyl, and (meth) acrylate represents each of acrylate and methacrylate.

Specific examples of the polyfunctional (meth)acrylate monomer may include those described in, for example, JP-A No. 2019-132930. Among them, those having 3 or more and 6 or less (meth) acryloyl groups in one molecule are preferable from the viewpoint of high reactivity, and increasing the surface hardness of the functional layer so as to improve the chafing resistance. As such a polyfunctional (meth)acrylate monomer, for example, pentaerythritol triacrylate (PETA), dipentaerythritol hexaacrylate (DPHA), pentaerythritol tetraacrylate (PETTA), dipentaerythritol pentaacrylate (DPPA), trimethylolpropane tri(meth)acrylate, tripentaerythritol octa(meth)acrylate, and tetrapentaerythritol deca(meth)acrylate may be preferably used. In particular, at least one kind selected from pentaerythritol tri(meth)acrylate, dipentaerythritol penta(meth)acrylate, and dipentaerythritol hexaacrylate is preferable.

Also, when the radical polymerizable compound is used, the chafing resistance may be decreased due to the flexible group in the molecular structure. Therefore, in order to suppress the decrease in the chafing resistance due to the flexible components (soft segments), it is preferable to use a radical polymerizable compound wherein a flexible group is not introduced into the molecular structure. Specifically, it is preferable to use a radical polymerizable compound that is not EO or PO modified. By using such a radical polymerizable compound, the crosslinking point may be increased and the chafing resistance may be improved.

In order to adjust the hardness or viscosity, or to improve the close adhesiveness, the functional layer may include a monofunctional (meth) acrylate monomer as the radical polymerizable compound. Specific examples of the monofunctional (meth) acrylate monomer may include those described in, for example, Japanese Patent Application Laid-Open (JP-A) No. 2019-132930.

The cation polymerizable compound is a compound including a cation polymerizable group. The cation polymerizable group included in the cation polymerizable compound may be a functional group capable of generating a cation polymerization reaction, and is not particularly limited; and examples thereof may include an epoxy group, an oxetanyl group, and a vinyl ether group. Incidentally, when the cation polymerizable compound includes two or more cation polymerizable groups, these cation polymerizable groups may be the same, and may be different from each other.

The number of the cation polymerizable groups included in one molecule of the cation polymerizable compound is preferably two or more, and more preferably three or more, from the viewpoint of increasing the surface hardness of the functional layer so as to improve the chafing resistance.

Also, among the above, as a cation polymerizable compound, a compound including at least one kind of an epoxy group and an oxetanyl group as a cation polymerizable group is preferable, and a compound including two or more of at least one kind of an epoxy groups and an oxetanyl groups in one molecule is more preferable. A cyclic ether group such as an epoxy group and an oxetanyl group is preferable from the viewpoint that shrinkage associated with the polymerization reaction is small. Also, a compound including the epoxy group among the cyclic ether groups has advantages in that compounds having various structure may be easily obtained; the durability of the obtained functional layer is not adversely affected; and the compatibility with the radical polymerizable compound may be easily controlled. Also, the oxetanyl group among the cyclic ether groups has advantages in that the degree of polymerization is high compared with the epoxy group; the toxicity is low; and when the obtained functional layer is combined with a compound including an epoxy group, the network forming rate obtained from the cationic polymerizable compound in the coating film is accelerated; and an independent network is formed without leaving unreacted monomers in the film even in a region mixed with the radical polymerizable compound.

Examples of the cationic polymerizable compound including an epoxy group may include an alicyclic epoxy resins such as polyglycidyl ether of a polyhydric alcohol including an alicyclic ring, or resins obtained by epoxidizing a compound including a cyclohexene ring or a cyclopentene ring, with a suitable oxidizing agent such as hydrogen peroxide and a peracid; an aliphatic epoxy resins such as polyglycidyl ether of aliphatic polyhydric alcohol or alkylene oxide adduct thereof, polyglycidyl ester of aliphatic long-chain polybasic acid, or homopolymer or copolymer of glycidyl (meth)acrylate; a glycidyl ether type epoxy resin such as glycidyl ether produced by the reaction of bisphenols such as bisphenol A, bisphenol F, and hydrogenated bisphenol A, or derivative thereof such as alkylene oxide adduct and caprolactone adduct with epichlorohydrin, and resins that is novolac epoxy resin and derived from bisphenols.

Specific examples of the cationic polymerizable compound including the alicyclic epoxy resin, the glycidyl ether type epoxy resin, and an oxetanyl group may include those described in, for example, JP-A No. 2018-104682.

Also, when the functional layer has no hard coating properties, examples of the resin may include thermoplastic resins and curable resins. Incidentally, the curable resin is referred to as resins cured by heat or irradiation of ionizing radiation such as ultraviolet rays or electron beams.

### (c) Additives

The functional layer may include a polymerization initiator if necessary. As the polymerization initiator, a radical polymerization initiator, a cation polymerization initiator, and a radical and cation polymerization initiator may be appropriately selected and used. These polymerization initiators are decomposed by at least one kind of light irradiation and heating to generate radicals or cations to cause radical polymerization and cation polymerization to proceed. Incidentally, all of the polymerization initiators may be decomposed and may not be left in the functional layer, in some cases.

The functional layer may include an additive such as inorganic particles, organic particles, an antioxidant, a light stabilizer, an antistatic agent, an antiglare agent, a leveling agent, a surfactant, an easy lubricant, various sensitizers, a flame retardant, an adhesive imparting agent, a polymerization inhibitor, and a surface modifier, if necessary.

Incidentally, each component included in the functional layer may be analyzed by, for example, a Fourier transform infrared spectroscopy (FTIR), a pyrolysis gas chromatography mass spectrometry (GC-MS), a high-speed liquid chromatography, a gas chromatography mass spectrometry, a NMR, an element analyzer, an XPS/ESCA, a TOF-SIMS, and a combination of these.

### (2) Thickness of Functional Layer

The thickness of the functional layer is not particularly limited, as long as it is a thickness capable of obtaining a stacked body for a display device satisfying the difference of the crack elongation before and after the light resistance test, and it is appropriately selected according to the function of the functional layer. The thickness of the functional layer is preferably, for example, 0.5 μm or more and 50 μm or less, more preferably 1.0 μm or more and 40 μm or less, further preferably 1.5 μm or more and 30 μm or less, and particularly preferably 2.0 μm or more and 20 μm or less. When the thickness of the functional layer is too thin, the desired function may not be obtained. Also, when the thickness of the functional layer is too thick, the flexibility or bending resistance may be decreased.

Here, the thickness of the functional layer is the average value of the thickness of arbitrary 10 points obtained by measuring from the thickness directional cross-section of the stacked body for a display device by observing with a transmission electron microscope (TEM), a scanning electron microscope (SEM) or a scanning transmission electron microscope (STEM). Incidentally, the same is applied to the measuring methods of the thickness of other layers included in the stacked body for a display device.

Also, for example, when the functional layer is an ultraviolet absorber-containing hard coating layer including an ultraviolet absorber and resin, the product of the content (parts by mass) of the ultraviolet absorber with respect to 100 parts by mass of the resin in the ultraviolet absorber-containing hard coating layer; and the thickness (μm) of the ultraviolet absorber-containing hard coating layer is preferably 110 or more and 350 or less, more preferably 150 or more and 220 or less, and further preferably 180 or more and 220 or less. When the product is too low, the content of the ultraviolet absorber is low so that the effect of suppressing the ultraviolet ray deterioration in the polyimide substrate or ultraviolet absorber-containing hard coating layer, may not be obtained. Also, when the product is too low, the thickness of the ultraviolet absorber-containing hard coating layer is thin so that the desired function may not be obtained. Meanwhile, when the product is too high, the content of the ultraviolet absorber is increased. Therefore, the ultraviolet absorber-containing hard coating layer may not be sufficiently cured so that the close adhesiveness between the ultraviolet absorber-containing hard coating layer and the polyimide substrate may be decreased, and the bending resistance may be decreased. Also, coloring such as yellowing of the ultraviolet absorber-containing hard coating layer may occur depending on the type of the ultraviolet absorber, and the transparency of the stacked body for a display device may be decreased. Also, when the product is too high, the thickness of the ultraviolet absorber-containing hard coating layer is too thick so that the flexibility or bending resistance may be decreased.

Also, for example, when the functional layer is an ultraviolet absorbing layer including an ultraviolet absorber and resin, and when the stacked body for a display device includes a hard coating layer, a polyimide substrate, and an ultraviolet absorbing layer in this order, the product of the content (parts by mass) of the ultraviolet absorber with respect to 100 parts by mass of the resin in the ultraviolet absorbing layer; and the thickness (μm) of the ultraviolet absorbing layer is preferably 70 or more and 280 or less, more preferably 75 or more and 250 or less, further preferably 120 or more and 200 or less, and particularly preferably 150 or more and 200 or less. When the product is too low, the content of the ultraviolet absorber is low so that the effect of suppressing the ultraviolet ray deterioration in the polyimide substrate or ultraviolet absorbing layer, may not be obtained sufficiently. Meanwhile, when the product is too high, the content of the ultraviolet absorber is increased. Therefore, the ultraviolet absorbing layer may not be sufficiently cured so that the close adhesiveness between the ultraviolet absorbing layer and the polyimide substrate may be decreased, and the bending resistance may be decreased. Also, coloring such as yellowing of the ultraviolet absorbing layer may occur depending on the type of the ultraviolet absorber, and the transparency of the stacked body for a display device may be decreased. Also, when the product is too high, the thickness of the ultraviolet absorbing layer is too thick so that the flexibility or bending resistance may be decreased.

Also, for example, when the functional layer is an ultraviolet absorber-containing hard coating layer including an ultraviolet absorber and resin, the product of the ratio, in the infrared absorption spectrum measured by an infrared spectroscopy of the ultraviolet absorber-containing hard coating layer, of the peak strength of the peak deriving from a triazole ring included in the ultraviolet absorber with respect to the peak strength of the peak deriving from a carbonyl bond; and a thickness (μm) of the ultraviolet absorber-containing hard coating layer is preferably 4.1 or more and 10.8 or less, more preferably 5.2 or more and 7.6 or less, further preferably 5.7 or more and 7.1 or less, and particularly preferably 6.0 or more and 6.8 or less. Incidentally, “infrared absorption spectrum” may be hereinafter referred to as “IR spectrum” in some cases. In the IR spectrum of the ultraviolet absorber-containing hard coating layer, the ratio of the peak strength of the peak deriving from a triazole ring included in the ultraviolet absorber with respect to the peak strength of the peak deriving from a carbonyl bond is an index of the content of the ultraviolet absorber included in the ultraviolet absorber-containing hard coating layer. When the ratio, of the peak strength of the peak deriving from a triazole ring included in the ultraviolet absorber with respect to the peak strength of the peak deriving from a carbonyl bond, is higher, it is suggested that the content of the ultraviolet absorber in the ultraviolet absorber-containing hard coating layer is higher. Therefore, when the product is too low, the content of the ultraviolet absorber is low so that the effect of suppressing the ultraviolet ray deterioration in the polyimide substrate or ultraviolet absorber-containing hard coating layer, may not be obtained sufficiently. Also, when the product is too low, the thickness of the ultraviolet absorber-containing hard coating layer is thin so that the desired function may not be obtained. Meanwhile, when the product is too high, the content of the ultraviolet absorber is increased. Therefore, the ultraviolet absorber-containing hard coating layer may not be sufficiently cured so that the close adhesiveness between the ultraviolet absorber-containing hard coating layer and the polyimide substrate may be decreased, and the bending resistance may be decreased. Also, coloring such as yellowing of the ultraviolet absorber-containing hard coating layer may occur depending on the type of the ultraviolet absorber, and the transparency of the stacked body for a display device may be decreased. Also, when the product is too high, the thickness of the ultraviolet absorber-containing hard coating layer is too thick so that the flexibility or bending resistance may be decreased.

In the IR spectrum of the ultraviolet absorber-containing hard coating layer, the ratio of the peak strength of the peak deriving from a triazole ring included in the ultraviolet absorber with respect to the peak strength of the peak deriving from a carbonyl bond is, for example, 0.55 or more and 0.98 or less, may be 0.6 or more and 0.9 or less, and may be 0.7 or more and 0.8 or less. When the ratio of the peak strength is too low, the content of the ultraviolet absorber in the ultraviolet absorber-containing hard coating layer is low so that the effect of suppressing the ultraviolet ray deterioration in the polyimide substrate or ultraviolet absorber-containing hard coating layer, may not be obtained sufficiently. Meanwhile, when the ratio of the peak strength is too high, the content of the ultraviolet absorber in the ultraviolet absorber-containing hard coating layer is high so that the ultraviolet absorber-containing hard coating layer may not be sufficiently cured so that the close adhesiveness between the ultraviolet absorber-containing hard coating layer and the polyimide substrate may be decreased, and the bending resistance may be decreased. Also, coloring such as yellowing of the ultraviolet absorber-containing hard coating layer may occur depending on the type of the ultraviolet absorber, and the transparency of the stacked body for a display device may be decreased.

Also, for example, when the functional layer is an ultraviolet absorbing layer including an ultraviolet absorber and resin, and when the stacked body for a display device includes a hard coating layer, a polyimide substrate, and an ultraviolet absorbing layer in this order, the product of the ratio, in the infrared absorption spectrum measured by an infrared spectroscopy of the ultraviolet absorbing layer, of the peak strength of the peak deriving from a triazole ring included in the ultraviolet absorber with respect to the peak strength of the peak deriving from a carbonyl bond; and a thickness (μm) of the ultraviolet absorbing layer is preferably 2.5 or more and 7.8 or less, more preferably 3.8 or more and 6.2 or less, and further preferably 4.3 or more and 5.1 or less. In the IR spectrum of the ultraviolet absorbing layer, the ratio of the peak strength of the peak deriving from a triazole ring included in the ultraviolet absorber with respect to the peak strength of the peak deriving from a carbonyl bond is an index of the content of the ultraviolet absorber included in the ultraviolet absorbing layer. When the ratio, of the peak strength of the peak deriving from a triazole ring included in the ultraviolet absorber with respect to the peak strength of the peak deriving from a carbonyl bond, is higher, it is suggested that the content of the ultraviolet absorber in the ultraviolet absorbing layer is higher. Therefore, when the product is too low, the content of the ultraviolet absorber is low so that the effect of suppressing the ultraviolet ray deterioration in the polyimide substrate or hard coating layer, may not be obtained sufficiently.

Meanwhile, when the product is too high, the content of the ultraviolet absorber is increased. Therefore, the ultraviolet absorbing layer may not be sufficiently cured so that the close adhesiveness between the ultraviolet absorbing layer and the polyimide substrate may be decreased, and the bending resistance may be decreased. Also, coloring such as yellowing of the ultraviolet absorbing layer may occur depending on the type of the ultraviolet absorber, and the transparency of the stacked body for a display device may be decreased. Also, when the product is too high, the thickness of the ultraviolet absorbing layer is too thick so that the flexibility or bending resistance may be decreased.

In the IR spectrum of the ultraviolet absorbing layer, the ratio of the peak strength of the peak deriving from a triazole ring included in the ultraviolet absorber with respect to the peak strength of the peak deriving from a carbonyl bond is, for example, 0.83 or more and 1.55 or less, may be 1.26 or more and 1.55 or less, and may be 1.4 or more and 1.55 or less. When the ratio of the peak strength is too low, the content of the ultraviolet absorber in the ultraviolet absorbing layer is low so that the effect of suppressing the ultraviolet ray deterioration in the polyimide substrate or hard coating layer, may not be obtained sufficiently. Meanwhile, when the ratio of the peak strength is too high, the content of the ultraviolet absorber in the ultraviolet absorbing layer is high so that the ultraviolet absorbing layer may not be sufficiently cured so that the close adhesiveness between the ultraviolet absorbing layer and the polyimide substrate may be decreased, and the bending resistance may be decreased. Also, coloring such as yellowing of the ultraviolet absorbing layer may occur depending on the type of the ultraviolet absorber, and the transparency of the stacked body for a display device may be decreased.

Here, in the IR spectrum the peak deriving from a carbonyl bond is a peak comes up around 1720 cm⁻¹. The peak comes up around the wavenumber may be surmised to be a peak deriving from the carbonyl bond (C═O bond) of the (meta) acryloyl group. The carbonyl bond of the (meta) acryloyl group may be included not only in the resin but also in the ultraviolet absorber, when the ultraviolet absorber is polymer or oligomer. Incidentally, around 1720 cm⁻¹ refers to the tolerance range based on 1720 cm⁻¹, and is the wavenumber range of 1720±5 cm⁻¹. The tolerance range described above may be 1720±3 cm⁻¹, and may be 1720 #1 cm⁻¹.

Also, in the IR spectrum, the peak deriving from a triazole ring included in the ultraviolet absorber is a peak comes up around 1482 cm⁻¹. The peak comes up around the wavenumber may be surmised to be a peak deriving from a bond including N of the triazole ring. Incidentally, around 1482 cm⁻¹ refers to the tolerance range based on 1482 cm⁻¹, and is the wavenumber range of 1482±5 cm⁻¹. The tolerance range described above may be 1482±3 cm⁻¹, and may be 1482±1 cm⁻¹.

The IR spectrum may be measured by one-time reflection ATR method using Fourier transform infrared spectrophotometer (FT-IR). In the IR spectrum, the horizontal axis is the wavenumber and the vertical axis is the absorption. The measurement method is shown below. Firstly, an accessory device is installed in the spectrometer, and the stacked body for a display device is cut out into a desired size (a few centimeters square). When measuring the IR spectrum of the ultraviolet absorber-containing hard coating layer, the stacked body for a display device is set so that the surface of the ultraviolet absorber-containing hard coating layer faces the accessory device, and the single-reflection spectrum, when the surface of the ultraviolet absorber-containing hard coating layer is irradiated with infrared rays, is measured. Also, when measuring the IR spectrum of the ultraviolet absorbing layer, the stacked body for a display device is set so that the surface of the ultraviolet absorbing layer faces the accessory device, and the single-reflection spectrum, when the surface of the ultraviolet absorbing layer is irradiated with infrared rays, is measured. Incidentally, when measuring, by adjusting the penetration depth of light according to the thickness of the ultraviolet absorber-containing hard coating layer or the ultraviolet absorbing layer, the IR spectrum of the ultraviolet absorber-containing hard coating layer or the ultraviolet absorbing layer may be measured in a state of the stacked body for a display device. The measurement conditions are shown below.

### (Measurement Conditions)

Spectrometer: Fourier transform infrared spectrophotometer FTS-7000 (from Digital Laboratory, Inc.)
Accessory device: attachment for single-reflection ATR:
Silver Gate Evolution (from Specac Ltd.)
Prism: Ge crystal.
Incident angle: 45° incident
Measuring wavenumber range: from 700 cm⁻¹ to 4000 cm⁻¹
Resolution: 4 cm⁻¹
Scan speed: 20 kHz
Cumulative number: 64 times

The ratio of the peak strength, in the IR spectrum, of the ultraviolet absorber-containing hard coating layer is applied when the ultraviolet absorber-containing hard coating layer includes a benzotriazole based ultraviolet absorber as the ultraviolet absorber, and a cured product of (meth)acrylate as the resin.

Also, the ratio of the peak strength, in the IR spectrum, of the ultraviolet absorbing layer is applied when the ultraviolet absorbing layer includes a benzotriazole based ultraviolet absorber as the ultraviolet absorber, and a cured product of (meth)acrylate as the resin.

### (4) Constitution of Functional Layer

The functional layer may be a single layer, and may be a multilayer.

For example, when the functional layer is an ultraviolet absorber-containing hard coating layer including the ultraviolet absorber and resin, and when the ultraviolet absorber-containing hard coating layer is a multilayer, at least one of the layers constituting the ultraviolet absorber-containing hard coating layer have only to include an ultraviolet absorber. In this case, any one of the layers constituting the ultraviolet absorber-containing hard coating layer may include an ultraviolet absorber.

Also, for example, when the functional layer is an ultraviolet absorber-containing hard coating layer including the ultraviolet absorber and resin, and when the ultraviolet absorber-containing hard coating layer is a multilayer, in order to improve the surface hardness, and also to improve the bending resistance, for example, the functional layer preferably includes a layer configured to satisfy the pencil hardness and a layer configured to satisfy the dynamic bending test (a layer configured to satisfy the scratch resistance). Further, in this case, the ultraviolet absorber-containing hard coating layer preferably includes a layer configured to satisfy the pencil hardness and a layer configured to satisfy the dynamic bending test (a layer configured to satisfy the scratch resistance) in this order from the polyimide substrate side.

### (5) Method for Forming Functional Layer

Examples of a method for forming a functional layer may include a method wherein the substrate layer is coated with a resin composition for a functional layer, and cured.

### 3. Polyimide Substrate

The polyimide substrate in the present embodiment is a member configured to support the functional layer, and has transparency.

### (1) Material of Polyimide Substrate

The polyimide substrate includes polyimide based resins. Examples of the polyimide based resin may include polyimide, polyamideimide, polyetherimide, and polyesterimide. In particular, polyimide and polyamideimide are preferably used from the viewpoint of flexibility and bending resistance.

### (a) Polyimide

The polyimide is obtained by reacting a tetracarboxylic acid component and a diamine component. The polyimide is not particularly limited as long as it has transparency and stiffness; and it is preferable to have at least one kind of the structure selected from the group consisting of the structure represented by the following general formula (1) and the following general formula (3), for example, from the viewpoint of having excellent transparency and excellent stiffness.

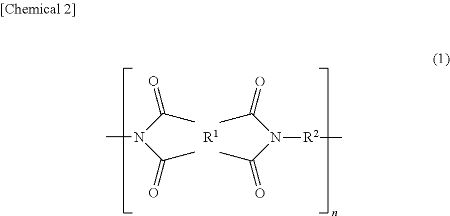

In the general formula (1), R¹ represents a tetravalent group which is a tetracarboxylic acid residue; and R² represents at least one kind of divalent group selected from the group consisting of a trans-cyclohexanediamine residue, a trans-1,4-bismethylenecyclohexanediamine residue, a 4,4′-diaminodiphenylsulfone residue, a 3,4′-diaminodiphenylsulfone residue, and a divalent group represented by the following general formula (2). The “n” represents the number of repeating units, and is 1 or more.

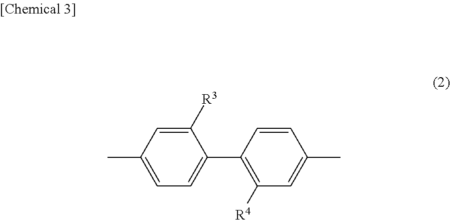

In the general formula (2), R³ and R⁴ each independently represents a hydrogen atom, an alkyl group, or a perfluoroalkyl group.

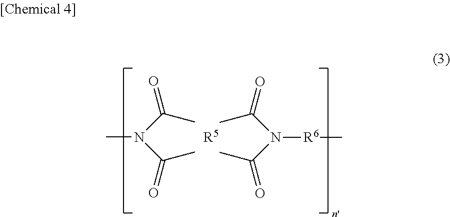

In the general formula (3), R⁵ represents at least one kind of tetravalent group selected from the group consisting of a cyclohexane tetracarboxylic acid residue, a cyclopentanetetracarboxylic acid residue, a dicyclohexane-3,4,3′,4′-tetracarboxylic acid residue, and a 4,4′-(hexafluoroisopropylidene)diphthalic acid residue; and R⁶ represents a divalent group which is a diamine residue. The “n′” represents the number of repeating units, and is 1 or more.

Incidentally, “tetracarboxylic acid residue” refers to a residue obtained by excluding four carboxyl groups from a tetracarboxylic acid; and represents the same structure as a residue obtained by excluding an acid dianhydride structure from a tetracarboxylic acid dianhydride. Also, “diamine residue” refers to a residue obtained by excluding two amino groups from a diamine.

In the general formula (1), R¹ is a tetracarboxylic acid residue, and may be a residue obtained by excluding an acid dianhydride structure from a tetracarboxylic acid dianhydride. Examples of the tetracarboxylic acid dianhydride may include those described in WO 2018/070523. Among them, R¹ in the general formula (1) preferably includes at least one kind selected from the group consisting of a 4,4′-(hexafluoroisopropylidene)diphthalic acid residue, a 3,3′,4,4′-biphenyltetracarboxylic acid residue, pyromellitic acid residue, a 2,3′,3,4′-biphenyltetracarboxylic acid residue, a 3,3′,4,4′-benzophenone tetracarboxylic acid residue, a 3,3′,4,4′-diphenylsulfone tetracarboxylic acid residue, a 4,4′-oxydiphthalic acid residue, a cyclohexane tetracarboxylic acid residue, and a cyclopentane tetracarboxylic acid residue from the viewpoint of improved transparency and improved stiffness. It is further preferable to include at least one kind selected from the group consisting of a 4,4′-(hexafluoroisopropylidene)diphthalic acid residue, a 4,4′-oxydiphthalic acid residue and a 3,3′,4,4′-diphenylsulfone tetracarboxylic acid residue.

In R¹, these preferable residues are preferably included in total of 50 mol % or more, more preferably 70 mol % or more, and further preferably 90 mol % or more.

Also, as R¹, it is also preferable to use a mixture of the followings: a tetracarboxylic acid residue group (Group A) suitable for improving rigidity such as at least one kind selected from the group consisting of a 3,3′,4,4′-biphenyltetracarboxylic acid residue, a 3,3′,4,4′-benzophenone tetracarboxylic acid residue, and a pyromellitic acid residue; and a tetracarboxylic acid residue group (Group B) suitable for improving transparency such as at least one kind selected from the group consisting of a 4,4′-(hexafluoroisopropylidene)diphthalic acid residue, a 2,3′,3,4′-biphenyltetracarboxylic acid residue, a 3,3′,4,4′-diphenylsulfone tetracarboxylic acid residue, a 4,4′-oxydiphthalic acid residue, a cyclohexane tetracarboxylic acid residue, and a cyclopentanetetracarboxylic acid residue.

In this case, in relation to the content ratio of the tetracarboxylic acid residue group suitable for improving the rigidity (Group A) and the tetracarboxylic acid residue group suitable for improving transparency (Group B), with respect to 1 mol of the tetracarboxylic acid residue group suitable for improving transparency (Group B), the tetracarboxylic acid residue group suitable for improving rigidity (Group A) is preferably 0.05 mol or more and 9 mol or less, more preferably 0.1 mol or more and 5 mol or less, and further preferably 0.3 mol or more and 4 mol or less.

Among them, R² in the general formula (1) is preferably at least one kind of divalent group selected from the group consisting of a 4,4′-diaminodiphenylsulfone residue, a 3,4′-diaminodiphenylsulfone residue, and a divalent group represented by the general formula (2); and is further preferably at least one kind of divalent group selected from the group consisting of a 4,4′-diaminodiphenylsulfone residue, a 3,4′-diaminodiphenylsulfone residue, and a divalent group represented by the general formula (2) wherein R³ and R⁴ are a perfluoroalkyl group, from the viewpoint of improved transparency and improved stiffness.

Among them, from the viewpoint of improved transparency and improved stiffness, R⁵ in the general formula (3) preferably includes a 4,4′-(hexafluoroisopropylidene)diphthalic acid residue, a 3,3′,4,4′-diphenylsulfontetracarboxylic acid residue, and oxydiphthalic acid residue.

The R⁵ preferably includes 50 mol % or more, more preferably 70 mol % or more, and further preferably 90 mol % or more of these preferable residues.

The R⁶ in the general formula (3) is a diamine residue, and may be a residue obtained by excluding two amino groups from a diamine. Examples of the diamine may include those described in, for example, WO 2018/070523. Among them, from the viewpoint of improved transparency and improved stiffness, R⁶ in the general formula (3) preferably includes at least one kind of divalent group selected from the group consisting of a 2,2′-bis(trifluoromethyl)benzidine residue, a bis[4-(4-aminophenoxy)phenyl]sulfone residue, a 4,4′-diaminodiphenylsulfone residue, a 2,2-bis[4-(4-aminophenoxy)phenyl]hexafluoropropane residue, a bis[4-(3-aminophenoxy)phenyl]sulfone residue, a 4,4′-diamino-2,2′-bis(trifluoromethyl)diphenylether residue, a 1,4-bis[4-amino-2-(trifluoromethyl)phenoxy]benzene residue, a 2,2-bis[4-(4-amino-2-trifluoromethylphenoxy)phenyl]hexafluoropropane residue, a 4,4′-diamino-2-(trifluoromethyl)diphenyl ether residue, a 4,4′-diaminobenzanilide residue, a N,N′-bis(4-aminophenyl) terephthalamide residue and a 9,9-bis(4-aminophenyl)fluorene residue; and further preferably includes at least one kind of divalent group selected from the group consisting of a 2,2′-bis(trifluoromethyl)benzidine residue, a bis[4-(4-aminophenoxy)phenyl]sulfone residue, and a 4,4′-diaminodiphenylsulfone residue.

In R⁶, these preferable residues are preferably included in total of 50 mol % or more, more preferably 70 mol % or more, and further preferably 90 mol % or more.

Also, as R⁶, it is also preferable to use a mixture of the followings: a diamine residue group (Group C) suitable for improving rigidity such as at least one kind selected from the group consisting of a bis[4-(4-aminophenoxy)phenyl]sulfone residue, a 4,4′-diaminobenzanilide residue, a N,N′-bis(4-aminophenyl) terephthalamide residue, a paraphenylenediamine residue, a metaphenylenediamine residue, and a 4,4′-diaminodiphenylmethane residue; and a diamine residue group (Group D) suitable for improving transparency such as at least one kind selected from the group consisting of a 2,2′-bis(trifluoromethyl)benzidine residue, a 4,4′-diaminodiphenyl sulfone residue, a 2,2-bis[4-(4-aminophenoxy)phenyl]hexafluoropropane residue, a bis[4-(3-aminophenoxy)phenyl]sulfone residue, a 4,4′-diamino-2,2′-bis(trifluoromethyl)diphenylether residue, a 1,4-bis[4-amino-2-(trifluoromethyl)phenoxy]benzene residue, a 2,2-bis[4-(4-amino-2-trifluoromethylphenoxy)phenyl]hexafluoropropane residue, a 4,4′-diamino-2(trifluoromethyl)dipenylether residue, and a 9,9-bis(4-aminophenyl)fluorene residue.

In this case, in relation to the content ratio of the diamine residue group suitable for improving rigidity (Group C) and the diamine residue group suitable for improving transparency (Group D), with respect to 1 mol of the diamine residue group suitable for improving transparency (Group D), the diamine residue group suitable for improving rigidity (Group C) is preferably 0.05 mol or more and 9 mol or less, more preferably 0.1 mol or more and 5 mol or less, and further preferably 0.3 mol or more and 4 mol or less.

In the structure represented by the general formula (1) and the general formula (3), “n” and “n′” each independently represents the number of repeating units, and is 1 or more. The number of repeating units “n” in the polyimide may be appropriately selected according to the structure, and is not particularly limited. The average number of repeating units may be, for example, 10 or more and 2000 or less, and is preferably 15 or more and 1000 or less.

Also, the polyimide may include a polyamide structure in a part thereof. Examples of the polyamide structure that may be included may include a polyamideimide structure including a tricarboxylic acid residue such as trimellitic acid anhydride; and a polyamide structure including a dicarboxylic acid residue such as terephthalic acid.

From the viewpoint of improved transparency and improved surface hardness, at least one of the tetravalent group which is a tetracarboxylic acid residue of R¹ or R⁵, and the divalent group which is a diamine residue of R² or R⁶ preferably includes an aromatic ring; and preferably includes at least one selected from the group consisting of (i) a fluorine atom, (ii) an aliphatic ring, and (iii) a structure wherein aromatic rings are connected to each other by an alkylene group which may be substituted with a sulfonyl group or a fluorine. When the polyimide includes at least one kind selected from a tetracarboxylic acid residue including an aromatic ring, and a diamine residue including an aromatic ring, the molecular skeleton becomes rigid, the orientation property is increased, and the surface hardness is improved; however, the absorption wavelength of the rigid aromatic ring skeleton tends to be shifted to the longer wavelength side, and the transmittance of the visible light region tends to be decreased. Meanwhile, when the polyimide includes (i) a fluorine atom, the transparency is improved since it may make the electronic state in the polyimide skeleton to a state wherein a charge transfer is difficult. Also, when the polyimide includes (ii) an aliphatic ring, transparency is improved since the transfer of charge in the skeleton may be inhibited by breaking the conjugation of n electrons in the polyimide skeleton. Also, when the polyimide includes (iii) a structure wherein aromatic rings are connected to each other by an alkylene group which may be substituted with a sulfonyl group or a fluorine, transparency is improved since the transfer of charge in the skeleton may be inhibited by breaking the conjugation of n electrons in the polyimide skeleton.

Among them, from the viewpoint of improved transparency and improved surface hardness, at least one of the tetravalent group which is a tetracarboxylic acid residue of R¹ or R⁵, and the divalent group which is a diamine residue of R² or R⁶ preferably includes an aromatic ring and a fluorine atom; and the divalent group which is a diamine residue of R² or R⁶ preferably includes an aromatic ring and a fluorine atom.

Specific examples of such polyimide may include those having a specific structure described in WO 2018/070523.

The polyimide may be synthesized by a known method. Also, a commercially available polyimide may be used. Examples of the commercially available products of polyimide may include Neopulim (registered trademark) from Mitsubishi Gas Chemical Company, Inc.

The weight average molecular weight of the polyimide is preferably, for example, 3000 or more and 500,000 or less, more preferably 5000 or more and 300,000 or less, and further preferably 10,000 or more and 200,000 or less. When the weight average molecular weight is too low, sufficient strength may not be obtained, and when the weight average molecular weight is too high, the viscosity is increased and the solubility is decreased, so that a polyimide substrate having a smooth surface and uniform thickness may not be obtained in some cases.

Incidentally, the weight average molecular weight of the polyimide may be measured by gel permeation chromatography (GPC). Specifically, the polyimide is used as a N-methylpyrrolidone (NMP) solution having a concentration of 0.1% by mass; a 30 mmol % LiBr-NMP solution with a water content of 500 ppm or less is used as a developing solvent; and measurement is carried out using a GPC device (HLC-8120, used column: Shodex GPC LF-804 from Resonac Corporation) from Tosoh Corporation, under conditions of a sample injecting amount of 50 μL, a solvent flow rate of 0.4 mL/min, and at 37° C. The weight average molecular weight is determined on the basis of a polystyrene standard sample having the same concentration as that of the sample.

### (b) Polyamideimide

The polyamideimide is not particularly limited as long as it is able to obtain a resin substrate having transparency; and examples thereof may include those having a first block including a constituent unit derived from dianhydride, and a constituent unit derived from diamine; and a second block including a constituent unit derived from aromatic dicarbonyl compound, and a constituent unit derived from aromatic diamine. In the polyamideimide described above, the dianhydride may include, for example, biphenyltetracarboxylic acid dianhydride (BPDA) and 2-bis(3,4-dicarboxyphenyl)hexafluoropropanedianhydride (6FDA). Also, the diamine may include bistrifluoromethylbenzidine (TFDB). That is, the polyamideimide has a structure wherein a polyamideimide precursor including a first block wherein monomers including dianhydride and diamine are copolymerized; and a second block wherein monomers including an aromatic dicarbonyl compound and an aromatic diamine are copolymerized, is imidized. By including the first block including an imide bond and the second block including an amide bond, the polyamideimide is excellent in not only optical properties but also thermal and mechanical properties. In particular, by using bistrifluoromethylbenzidine (TFDB) as the diamine forming the first block, thermal stability and optical properties may be improved. Also, by using 2-bis(3,4-dicarboxyphenyl)hexafluoropropane dianhydride (6FDA) and biphenyltetracarboxylic acid dianhydride (BPDA) as the dianhydride forming the first block, birefringence may be improved, and heat resistance may be secured.

The dianhydride forming the first block comprises two kinds of dianhydrides, that is, 6FDA and BPDA. In the first block, a polymer to which TFDB and 6FDA are bonded, and a polymer to which TEDB and BPDA are bonded may be included, based on separate repeating units, respectively segmented; may be regularly arranged within the same repeating unit; and may be included in a completely random arrangement.

Among the monomers forming the first block, BPDA and 6FDA are preferably included as dianhydrides in a molar ratio of 1:3 to 3:1. This is because it is possible not only to secure the optical properties, but also to suppress decrease of mechanical properties and heat resistance, and it is possible to have excellent birefringence.

The molar ratio of the first block and the second block is preferably 5:1 to 1:1. When the content of the second block is remarkably low, the effect of improving the thermal stability and mechanical properties due to the second block may not be sufficiently obtained in some cases. Also, when the content of the second block is higher than the content of the first block, although the thermal stability and mechanical properties may be improved, optical properties such as yellowness and transmittance, may be deteriorated, and the birefringence property may also be increased in some cases. Incidentally, the first block and the second block may be random copolymers, and may be block copolymers. The repeating unit of the block is not particularly limited.

Examples of the aromatic dicarbonyl compound forming the second block may include one kind or more selected from the group consisting of terephthaloyl chloride (p-terephthaloyl chloride, TPC), terephthalic acid, iso-phthaloyl dichloride, and 4,4′-benzoyl dichloride (4,4′-benzoyl chloride). One kind or more selected from terephthaloyl chloride (p-terephthaloyl chloride, TPC) and iso-phthaloyl dichloride may be preferably used.

Examples of the diamine forming the second block may include diamines including one kind or more flexible group selected from the group consisting of 2,2-bis(4-(4-aminophenoxy)phenyl)hexafluoropropane (HFBAPP), bis(4-(4-aminophenoxy)phenyl)sulfone (BAPS), bis(4-(3-aminophenoxy)phenyl)sulfone (BAPSM), 4,4′-diaminodiphenyl sulfone (4DDS), 3,3′-diaminodiphenyl sulfone (3DDS), 2,2-bis(4-(4-aminophenoxy)phenylpropane (BAPP), 4,4′-diaminodiphenylpropane (6HDA), 1,3-bis(4-aminophenoxy)benzene (134APB), 1,3-bis(3-aminophenoxy)benzene (133APB), 1,4-bis(4-aminophenoxy)biphenyl (BAPB), 4,4′-bis(4-amino-2-trifluoromethylphenoxy)biphenyl (6FAPBP), 3,3-diamino-4,4-dihydroxydiphenylsulfone (DABS), 2,2-bis(3-amino-4-hydroxyloxyphenyl)propane (BAP), 4,4′-diaminodiphenylmethane (DDM), 4,4′-oxydianiline (4-ODA) and 3,3′-oxydianiline (3-ODA).

When the aromatic dicarbonyl compound is used, it is easy to realize high thermal stability and mechanical properties, but may exhibit high birefringence due to the benzene ring in the molecular structure. Therefore, in order to suppress the decrease in birefringence due to the second block, it is preferable to use a diamine wherein a flexible group is introduced into the molecular structure. Specifically, the diamine is more preferably one kind or more diamine selected from bis(4-(3-aminophenoxy)phenyl)sulfone (BAPSM), 4,4′-diaminodiphenylsulfone (4DDS) and 2,2-bis(4-(4-aminophenoxy)phenyl)hexafluoropropane (HFBAPP). In particular, the longer the length of the flexible group such as BAPSM, and a diamine including a substituent at meta position, the better the birefringence may be exhibited.

For the polyamideimide precursor including a first block wherein a dianhydride including a biphenyltetracarboxylic acid dianhydride (BPDA) and a 2-bis(3,4-dicarboxyphenyl)hexafluoropropanedianhydride (6FDA), and a diamine including bistrifluoromethylbenzidine (TFDB) are copolymerized; and a second block wherein an aromatic dicarbonyl compound and an aromatic diamine are copolymerized, in the molecular structure, the weight average molecular weight measured by GPC is preferably, for example, 200,000 or more and 215,000 or less, and the viscosity is preferably, for example, 2400 poise or more and 2600 poise or less.

The polyamideimide may be obtained by imidizing a polyamideimide precursor. Also, a polyamideimide film may be obtained using the polyamideimide. For a method for imidizing the polyamideimide precursor and a method for producing a polyamideimide film, JP-A No. 2018-506611, for example, may be referred.

### (2) Thickness of Polyimide Substrate

The thickness of the polyimide substrate is not particularly limited as long as it has a thickness capable of having flexibility, and is preferably, for example, 10 μm or more and 100 μm or less, and more preferably 25 μm or more and 80 μm or less. When the thickness of the polyimide substrate is in the above range, excellent flexibility may be obtained, and at the same time, sufficient hardness may be obtained. It is also possible to suppress curling of the stacked body for a display device. Furthermore, it is preferable in terms of reducing the weight of the stacked body for a display device.

### 4. Other Layers

The stacked body for a display device in the present embodiment may include another layer, in addition to the polyimide substrate, and the functional layer described above.

(1) Hard coating layer

In the present embodiment, when the functional layer is an ultraviolet absorbing layer including an ultraviolet absorber, for example, as shown in FIG. 4, the stacked body for a display device 1 may include a hard coating layer 6 on the polyimide substrate 2, on a surface opposite to the ultraviolet absorbing layer 5 (functional layer 3). The hard coating layer is a member to enhance the surface hardness. By placing the hard coating layer, chafing resistance may be improved.

As a material of the hard coating layer, for example, an organic material, an inorganic material, and an organic-inorganic composite material may be used.

Among the above, the material of the hard coating layer is preferably an organic material. As an organic material, for example, it is preferably a cured resin cured by heat or irradiation of ionizing radiation such as ultraviolet rays or electron beams. The cured resin may be similar to the resin used when the functional layer described above has a hard coating function.

The thickness of the hard coating layer may be appropriately selected according to the function of the hard coating layer and the use application of the stacked body for a display device. The thickness of the hard coating layer is preferably, for example, 0.5 μm or more and 50 μm or less, more preferably 1.0 μm or more and 40 μm or less, further preferably 1.5 μm or more and 30 μm or less, and particularly preferably 2.0 μm or more and 20 μm or less. When the thickness of hard coating layer is in the above range, sufficient hardness as the hard coating layer may be obtained.

Examples of a method for forming a hard coating layer may include a method wherein the polyimide substrate is coated with a resin composition for a hard coating layer, and cured.

### (2) Hard Coating Film

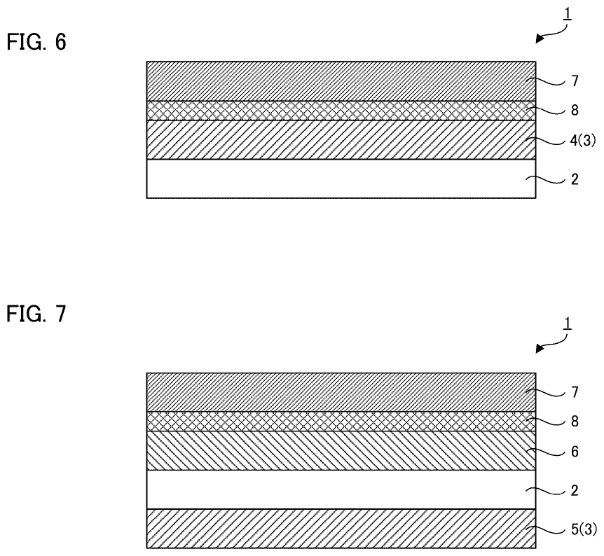

In the present embodiment, when the functional layer is an ultraviolet absorber-containing hard coating layer including an ultraviolet absorber, for example, as shown in FIG. 6, the stacked body for a display device 1 may include a hard coating film 7 on the ultraviolet absorber-containing hard coating layer 4 (functional layer 3), on a surface opposite to the polyimide substrate 2. By placing the hard coating film, the ultraviolet absorber-containing hard coating layer may be protected. Also, even when the hard coating properties are decreased due to the ultraviolet absorber-containing hard coating layer including the ultraviolet absorber, the hard coating properties are secured by including the hard coating film.

Also, in the present embodiment, when the functional layer is an ultraviolet absorbing layer including an ultraviolet absorber, and when the stacked body for a display device includes the ultraviolet absorbing layer, polyimide substrate, and hard coating layer in this order, for example, as shown in FIG. 7, the stacked body for a display device 1 may include a hard coating film 7 on the hard coating layer 6, on a surface opposite to the polyimide substrate 2. By placing the hard coating film, the hard coating layer may be protected.

The hard coating film includes, for example, a substrate layer, and a second hard coating layer placed on one surface of the substrate layer.

The material, thickness, and forming method, for example, of the second hard coating layer may be similar to the hard coating layer described above.

The substrate layer is not particularly limited, and the substrate layer commonly used in a hard coating film used in a stacked body for a display device may be used. Examples thereof may include polyethylene terephthalate (PET) substrate.

Also, the hard coating film may be placed, for example, via an adhesive layer. In this case, the adhesive layer, the substrate layer and the second hard coating layer may be placed in this order.

The adhesive layer has transparency. Specifically, the total light transmittance of the adhesive layer is preferably 85% or more, more preferably 88% or more, and further preferably 90% or more.

The adhesive used for the adhesive layer may be similar to the adhesive used for the interlayer adhesive layer described later.

The thickness of the adhesive layer is preferably, for example, 1 μm or more and 100 μm or less. When the thickness of the adhesive layer is too thick, the bending resistance may be deteriorated. Meanwhile, when the thickness of the adhesive layer is too thin, the adhesiveness may not be secured so as to be peeled off.

### (3) Second Hard Coating Layer

In the present embodiment, when the functional layer is an ultraviolet absorber-containing hard coating layer including an ultraviolet absorber, for example, as shown in FIG. 5B, the stacked body for a display device 1 may include a second hard coating layer 9 on the ultraviolet absorber-containing hard coating layer 4 (functional layer 3), on a surface opposite to the polyimide substrate 2. By placing the second hard coating layer, the ultraviolet absorber-containing hard coating layer may be protected. Also, even when the hard coating properties are decreased due to the ultraviolet absorber-containing hard coating layer including the ultraviolet absorber, the hard coating properties are secured by including the second hard coating layer.

The material, thickness, and forming method, for example, of the second hard coating layer may be similar to the hard coating layer described above.

### (4) Impact Absorbing Layer

In the stacked body for a display device in the present embodiment, when the functional layer is an ultraviolet absorber-containing hard coating layer including an ultraviolet absorber, an impact absorbing layer may be provided between the polyimide substrate and ultraviolet absorber-containing hard coating layer, or on the polyimide substrate, on a surface opposite side to the ultraviolet absorber-containing hard coating layer.

Also, in the stacked body for a display device in the present embodiment, when the functional layer is an ultraviolet absorbing layer including an ultraviolet absorber, and when the stacked body for a display device includes the ultraviolet absorbing layer, polyimide substrate, and hard coating layer in this order, an impact absorbing layer may be provided between the polyimide substrate and hard coating layer, between the polyimide substrate and ultraviolet absorbing layer, or on the ultraviolet absorbing layer, on a surface opposite side to the polyimide substrate.

By placing the impact absorbing layer, when an impact is imparted to the stacked body for a display device, the impact is absorbed so that the impact resistance may be improved.

The material of the impact absorbing layer is not particularly limited as long as it is capable of obtaining an impact absorbing layer having an impact absorbing property, and transparency, and examples thereof may include polyethylene terephthalate (PET), polyethylene naphthalate (PEN), urethane resin, epoxy resin, polyimide, polyamideimide, acrylic resin, triacetyl cellulose (TAC), and silicone resin. One kind of these materials may be used alone, and two kinds or more may be used in combination.

The impact absorbing layer may further include an additive if necessary. Examples of the additive may include inorganic particles, organic particles, an ultraviolet absorber, an antioxidant, a light stabilizer, a surfactant, and an adhesive improving agent.

The thickness of the impact absorbing layer may be the thickness capable of absorbing an impact, and is preferably, for example, 5 μm or more and 150 μm or less, more preferably 10 μm or more and 120 μm or less, and further preferably 15 μm or more and 100 μm or less.

As the impact absorbing layer, for example, a resin film may be used. Also, for example, the impact absorbing layer may be formed by coating the polyimide substrate with a composition for an impact absorbing layer.

### (5) Adhesive Layer for Adhesion

In the stacked body for a display device in the present embodiment, when the functional layer is an ultraviolet absorber-containing hard coating layer including an ultraviolet absorber, an adhesive layer for adhesion may be provided on the polyimide substrate, on a surface opposite side to the ultraviolet absorber-containing hard coating layer.

Also, in the stacked body for a display device in the present embodiment, when the functional layer is an ultraviolet absorbing layer including an ultraviolet absorber, and when the stacked body for a display device includes the ultraviolet absorbing layer, polyimide substrate, and hard coating layer in this order, an adhesive layer for adhesion may be provided on the ultraviolet absorbing layer, on a surface opposite side to the polyimide substrate.

The stacked body for a display device may be adhered to, for example, a display panel via the adhesive layer for adhesion.

The adhesive used for the adhesive layer for adhesion is not particularly limited as long as it is an adhesive having transparency, and is capable of adhering the stacked body for a display device to, for example, a display panel. Examples thereof may include a thermosetting adhesive, an ultraviolet curable adhesive, a two-component curable adhesive, a thermal fusion adhesive, and a pressure-sensitive adhesive (so-called tackiness agent).

In particular, when the functional layer is an ultraviolet absorber-containing hard coating layer including an ultraviolet absorber, and when an adhesive layer for adhesion is placed on the polyimide substrate, on the surface opposite side to the ultraviolet absorber-containing hard coating layer; or when the functional layer is an ultraviolet absorbing layer including an ultraviolet absorber, and the stacked body for a display device includes the ultraviolet absorbing layer, polyimide substrate, and hard coating layer in this order, and when an impact absorbing layer is placed on the ultraviolet absorbing layer, on a surface opposite side to the polyimide substrate, and when the interlayer adhesive layer described later, impact absorbing layer, and adhesive layer for adhesion are placed in this order from the polyimide substrate side, the adhesive layer for adhesion and the interlayer adhesive layer preferably include pressure-sensitive adhesive, that is, preferably a pressure-sensitive adhesive layer. Generally, the pressure-sensitive adhesive layer is relatively a soft layer among the adhesive layers including the adhesives described above. The impact resistance may be improved by including the impact absorbing layer between the pressure-sensitive adhesive layers those are relatively soft. Since the pressure-sensitive adhesive layer is relatively soft so as to be easily deformed, the impact absorbing layer is easily deformed when an impact is applied to the stacked body for a display device because the deformation of the impact absorbing layer is not suppressed by the pressure-sensitive adhesive layer so that higher impact absorbing effect is believed to be exhibited.

The thickness of the adhesive layer for adhesion is preferably, for example, 10 μm or more and 100 μm or less, more preferably 25 μm or more and 80 μm or less, and further preferably 40 μm or more and 60 μm or less. When the thickness of the adhesive layer for adhesion is too thin, the stacked body for a display device and the display panel may not be adhered sufficiently. Also, when the thickness of the adhesive layer for adhesion is too thick, the flexibility may be deteriorated.

As the adhesive layer for adhesion, for example, an adhesive film may be used. Also, for example, the adhesive layer for adhesion may be formed by coating a supporting body or the polyimide substrate, for example, with an adhesive composition.

### (6) Antifouling Layer

In the stacked body for a display device in the present embodiment, when the functional layer is an ultraviolet absorber-containing hard coating layer including an ultraviolet absorber, an antifouling layer may be provided on the ultraviolet absorber-containing hard coating layer, on a surface opposite side to the polyimide substrate.

Also, in the stacked body for a display device in the present embodiment, when the functional layer is an ultraviolet absorbing layer including an ultraviolet absorber, and when the stacked body for a display device includes the ultraviolet absorbing layer, polyimide substrate, and hard coating layer in this order, an antifouling layer may be provided on the hard coating layer, on a surface opposite side to the polyimide substrate.

By placing the antifouling layer, antifouling property may be imparted to the stacked body for a display device.

As the material of the antifouling layer, general antifouling layer materials may be applied.

The thickness of the antifouling layer is preferably, for example, 1 nm or more and 30 nm or less, more preferably 2 nm or more and 20 nm or less, and further preferably 3 nm or more and 10 nm or less. When the thickness of the antifouling layer is in the above range, the antifouling property and durability may be improved.

A method for forming an antifouling layer may be appropriately selected according to the material of the antifouling layer, and examples thereof may include a method wherein the second layer is coated with a resin composition for an antifouling layer, and cured; a vacuum deposition method; and a sputtering method.

### (7) Interlayer Adhesive Layer

In the stacked body for a display device in the present disclosure, an interlayer adhesive layer may be placed between each layer.

The adhesive used for the interlayer adhesive layer may be similar to the adhesive used for the adhesive layer for adhesion described above.

The thickness of the interlayer adhesive layer, and the forming method, for example, may be similar to the thickness, and the forming method, for example, of the adhesive layer for adhesion described above.

### 5. Others Regarding Stacked Body for Display Device

The thickness of the stacked body for a display device in the present embodiment is preferably, for example, 10 μm or more and 500 μm or less, more preferably 20 μm or more and 400 μm or less, and further preferably 30 μm or more and 300 μm or less. When the thickness of the stacked body for a display device is in the above range, the flexibility may be improved.

The stacked body for a display device in the present embodiment may be used as a front panel placed on the observer side than the display panel in a display device. Among the above, the stacked body for a display device in the present embodiment may be preferably used as a front panel in a flexible display device such as a foldable display, a rollable display, and a bendable display. Particularly, the stacked body for a display device in the present embodiment is suitably used for the front panel in a foldable display, since it has good bending resistance.

Also, the stacked body for a display device in the present embodiment may be used for the front panel in a display device such as an organic EL display device, and a liquid crystal display device. In particular, since the stacked body for a display device in the present embodiment is able to suppress ultraviolet ray deterioration and is able to suppress the decrease in the bending properties, it is suitable for the front panel in an organic EL display device including no circular polarizing plate. In this case, deterioration due to light emission from external light or organic EL element may be suppressed, and good bending properties may be obtained.

Also, the stacked body for a display device in the present embodiment may be used as a front panel in a display device such as smart phones, tablet terminals, wearable terminals, personal computers, televisions, digital signages, public information displays (PIDs), and car mounted displays.

### II. Second Embodiment

The second embodiment of the stacked body for a display device in the present disclosure comprises a polyimide substrate, and an ultraviolet absorber-containing hard coating layer including an ultraviolet absorber and resin, placed on one surface of the polyimide substrate, wherein a product of a content (parts by mass) of the ultraviolet absorber with respect to 100 parts by mass of the resin in the ultraviolet absorber-containing hard coating layer; and a thickness (μm) of the ultraviolet absorber-containing hard coating layer is 110 or more and 350 or less.

FIG. 3 is a schematic cross-sectional view illustrating an example of a stacked body for a display device in the present embodiment. As shown in FIG. 3, a stacked body for a display device 1 comprises a polyimide substrate 2, and an ultraviolet absorber-containing hard coating layer 4 including an ultraviolet absorber and resin, placed on one surface of the polyimide substrate 2. Also, in the stacked body for a display device 1, a product of a content (parts by mass) of the ultraviolet absorber with respect to 100 parts by mass of the resin in the ultraviolet absorber-containing hard coating layer 4; and a thickness (μm) of the ultraviolet absorber-containing hard coating layer 4 is in a predetermined range.

In the present embodiment, since the ultraviolet absorber-containing hard coating layer includes an ultraviolet absorber, and further, since the product of a content (parts by mass) of the ultraviolet absorber with respect to 100 parts by mass of the resin in the ultraviolet absorber-containing hard coating layer; and a thickness (μm) of the ultraviolet absorber-containing hard coating layer is in a predetermined range, the ultraviolet ray deterioration of the polyimide substrate and ultraviolet absorber-containing hard coating layer may be suppressed, and the decrease in the close adhesiveness between the polyimide substrate and ultraviolet absorber-containing hard coating layer in relation thereto may be suppressed. As the result, the decrease in bending resistance due to the decrease in close adhesiveness between the polyimide substrate and ultraviolet absorber-containing hard coating layer may be suppressed, and good bending resistance may be obtained. Also, since the ultraviolet absorber-containing hard coating layer includes an ultraviolet absorber, ultraviolet deterioration of the polyimide substrate may be suppressed; the color change of the polyimide substrate over time may be suppressed; and a stacked body for a display device with good transparency may be obtained.

In the present embodiment, the polyimide substrate, ultraviolet absorber-containing hard coating layer, and other layers constituting the stacked body for a display device, and the properties, thickness, and use application, for example, of the stacked body for a display device may be similar to those in the first embodiment, so the description herein is omitted.

### III. Third Embodiment

The third embodiment of the stacked body for a display device in the present disclosure comprises a hard coating layer, a polyimide substrate, and an ultraviolet absorbing layer including an ultraviolet absorber and resin, in this order, wherein a product of a content (parts by mass) of the ultraviolet absorber with respect to 100 parts by mass of the resin in the ultraviolet absorbing layer; and a thickness (μm) of the ultraviolet absorbing layer is 70 or more and 280 or less.

FIG. 4 is a schematic cross-sectional view illustrating an example of a stacked body for a display device in the present embodiment. As shown in FIG. 4, a stacked body for a display device 1 comprises an ultraviolet absorbing layer 5 including an ultraviolet absorber and resin; a polyimide substrate 2; and a hard coating layer 6 in this order. Also, in the stacked body for a display device 1, a product of a content (parts by mass) of the ultraviolet absorber with respect to 100 parts by mass of the resin in the ultraviolet absorbing layer 5; and a thickness (μm) of the ultraviolet absorbing layer 5 is in a predetermined range.

In the present embodiment, since the ultraviolet absorbing layer includes an ultraviolet absorber, and further, since the product of a content (parts by mass) of the ultraviolet absorber with respect to 100 parts by mass of the resin in the ultraviolet absorbing layer; and a thickness (μm) of the ultraviolet absorbing layer is in a predetermined range, the ultraviolet ray deterioration of the polyimide substrate and hard coating layer may be suppressed, and the decrease in the close adhesiveness between the polyimide substrate and hard coating layer in relation thereto may be suppressed. As the result, the decrease in bending resistance due to the decrease in close adhesiveness between the polyimide substrate and hard coating layer may be suppressed, and good bending resistance may be obtained. Also, since the ultraviolet absorbing layer includes an ultraviolet absorber, ultraviolet deterioration of the polyimide substrate may be suppressed; the color change of the polyimide substrate over time may be suppressed; and a stacked body for a display device with good transparency may be obtained.

In the present embodiment, the polyimide substrate, ultraviolet absorbing layer, hard coating layer, and other layers constituting the stacked body for a display device, and the properties, thickness, and use application, for example, of the stacked body for a display device may be similar to the first embodiment, so the description herein is omitted.

IV. Fourth embodiment

The fourth embodiment of the stacked body for a display device comprises a polyimide substrate, and a functional layer including an ultraviolet absorber, placed on one surface of the polyimide substrate, wherein a crack elongation of the stacked body for a display device measured by the following method, after the following light resistance test, is 3.0% or more and 6.0% or less.

Light resistance test: xenon light is irradiated for 60 hours from a functional layer side surface of the stacked body for a display device under conditions of a temperature of 50° C., humidity of 50% RH, wavelength range of 300 nm or more and 400 nm or less, and radiation illuminance of 60 W/m².

Method for measuring crack elongation: using a test piece of a size of 3 mm width and 100 mm length, a tensile length when a crack occurs in the stacked body for a display device is measured under conditions of a temperature of 23±5° C., humidity of 30% RH or more and 70% RH or less, pulling speed of 10 mm/minute, and a distance between grips of 50 mm. The crack elongation is calculated from the following formula (1).

$$Crack elongation ( \% ) = 100 \times tensile length ( mm ) / distance between grips ( mm ) \qquad ( 1 )$$

FIG. 1 is a schematic cross-sectional view illustrating an example of a stacked body for a display device in the present embodiment. As shown in FIG. 1, a stacked body for a display device 1 comprises a polyimide substrate 2, and a functional layer 3 including an ultraviolet absorber, placed on one surface of the polyimide substrate 2. Also, in the stacked body for a display device 1, a crack elongation of the stacked body for a display device 1 measured by the method described above, after the light resistance test described above, is in a predetermined range.

In the present embodiment, by the functional layer including ultraviolet absorber, and further, by selecting the functional layer so that the crack elongation after the light resistance test is in a predetermined range, specifically, by adjusting the content of the ultraviolet absorber in the functional layer and the thickness of the functional layer, the ultraviolet ray deterioration in the polyimide substrate or functional layer may be suppressed, and the decrease in the close adhesiveness between the polyimide substrate and functional layer, due to thereof, may be suppressed. As the result, the decrease in bending resistance due to the decrease in close adhesiveness between the polyimide substrate and functional layer may be suppressed, and good bending resistance may be obtained. Also, since the functional layer includes an ultraviolet absorber, ultraviolet deterioration of the polyimide substrate may be suppressed; the color change of the polyimide substrate over time may be suppressed; and a stacked body for a display device with good transparency may be obtained.

In the present embodiment, the polyimide substrate, functional layer, and other layers constituting the stacked body for a display device, and the properties, thickness, and use application, for example, of the stacked body for a display device may be similar to the contents described in the first embodiment, so the description herein is omitted.

### V. Fifth Embodiment

The fifth embodiment of the stacked body for a display device in the present disclosure comprises a polyimide substrate, and an ultraviolet absorber-containing hard coating layer including an ultraviolet absorber and resin, placed on one surface of the polyimide substrate, wherein a product of a ratio, in an infrared absorption spectrum measured by an infrared spectroscopy of the ultraviolet absorber-containing hard coating layer, of a peak strength of a peak deriving from a triazole ring included in the ultraviolet absorber with respect to a peak strength of a peak deriving from a carbonyl bond; and a thickness (μm) of the ultraviolet absorber-containing hard coating layer is 4.1 or more and 10.8 or less.

FIG. 3 is a schematic cross-sectional view illustrating an example of a stacked body for a display device in the present embodiment. As shown in FIG. 3, a stacked body for a display device 1 comprises a polyimide substrate 2, and an ultraviolet absorber-containing hard coating layer 4 including an ultraviolet absorber and resin, placed on one surface of the polyimide substrate 2. Also, in the stacked body for a display device 1, the product of a ratio, in an infrared absorption spectrum measured by an infrared spectroscopy of the ultraviolet absorber-containing hard coating layer 4, of a peak strength of a peak deriving from a triazole ring included in the ultraviolet absorber with respect to a peak strength of a peak deriving from a carbonyl bond; and a thickness (μm) of the ultraviolet absorber-containing hard coating layer 4 is in a predetermined range.

In the present embodiment, since the ultraviolet absorber-containing hard coating layer includes an ultraviolet absorber, and further, since the product of a ratio, in an infrared absorption spectrum measured by an infrared spectroscopy of the ultraviolet absorber-containing hard coating layer, of a peak strength of a peak deriving from a triazole ring included in the ultraviolet absorber with respect to a peak strength of a peak deriving from a carbonyl bond; and a thickness (μm) of the ultraviolet absorber-containing hard coating layer is in a predetermined range, the ultraviolet ray deterioration of the polyimide substrate and ultraviolet absorber-containing hard coating layer may be suppressed, and the decrease in the close adhesiveness between the polyimide substrate and ultraviolet absorber-containing hard coating layer in relation thereto may be suppressed. As the result, the decrease in bending resistance due to the decrease in close adhesiveness between the polyimide substrate and ultraviolet absorber-containing hard coating layer may be suppressed, and good bending resistance may be obtained. Also, since the ultraviolet absorber-containing hard coating layer includes an ultraviolet absorber, ultraviolet deterioration of the polyimide substrate may be suppressed; the color change of the polyimide substrate over time may be suppressed; and a stacked body for a display device with good transparency may be obtained.

In the present embodiment, the polyimide substrate, ultraviolet absorber-containing hard coating layer, and other layers constituting the stacked body for a display device, and the properties, thickness, and use application, for example, of the stacked body for a display device may be similar to the contents described in the first embodiment, so the description herein is omitted.

### VI. Sixth Embodiment

The sixth embodiment of the stacked body for a display device in the present disclosure comprises a hard coating layer, a polyimide substrate, and an ultraviolet absorbing layer including an ultraviolet absorber and resin, in this order, wherein a product of a ratio, in an infrared absorption spectrum measured by an infrared spectroscopy of the ultraviolet absorbing layer, of a peak strength of a peak deriving from a triazole ring included in the ultraviolet absorber with respect to a peak strength of a peak deriving from a carbonyl bond; and a thickness (μm) of the ultraviolet absorbing layer is 2.5 or more and 7.8 or less.

FIG. 4 is a schematic cross-sectional view illustrating an example of a stacked body for a display device in the present embodiment. As shown in FIG. 4, a stacked body for a display device 1 comprises an ultraviolet absorbing layer 5 including an ultraviolet absorber and resin; a polyimide substrate 2; and a hard coating layer 6 in this order. Also, in the stacked body for a display device 1, the product of a ratio, in an infrared absorption spectrum measured by an infrared spectroscopy of the ultraviolet absorbing layer 5, of a peak strength of a peak deriving from a triazole ring included in the ultraviolet absorber with respect to a peak strength of a peak deriving from a carbonyl bond; and a thickness (μm) of the ultraviolet absorbing layer 5 is in a predetermined range.

In the present embodiment, since the ultraviolet absorbing layer includes an ultraviolet absorber, and further, since the product of a ratio, in an infrared absorption spectrum measured by an infrared spectroscopy of the ultraviolet absorbing layer, of a peak strength of a peak deriving from a triazole ring included in the ultraviolet absorber with respect to a peak strength of a peak deriving from a carbonyl bond; and a thickness (μm) of the ultraviolet absorbing layer is in a predetermined range, the ultraviolet ray deterioration of the polyimide substrate and ultraviolet absorbing layer may be suppressed, and the decrease in the close adhesiveness between the polyimide substrate and ultraviolet absorbing layer in relation thereto may be suppressed. As the result, the decrease in bending resistance due to the decrease in close adhesiveness between the polyimide substrate and hard coating layer may be suppressed, and good bending resistance may be obtained. Also, since the ultraviolet absorbing layer includes an ultraviolet absorber, ultraviolet deterioration of the polyimide substrate may be suppressed; the color change of the polyimide substrate over time may be suppressed; and a stacked body for a display device with good transparency may be obtained.

In the present embodiment, the polyimide substrate, ultraviolet absorbing layer, hard coating layer, and other layers constituting the stacked body for a display device, and the properties, thickness, and use application, for example, of the stacked body for a display device may be similar to the contents described in the first embodiment, so the description herein is omitted.

### B. Display Device

The display device in the present disclosure comprises: a display panel, and the stacked body for a display device described above placed on an observer side of the display panel.

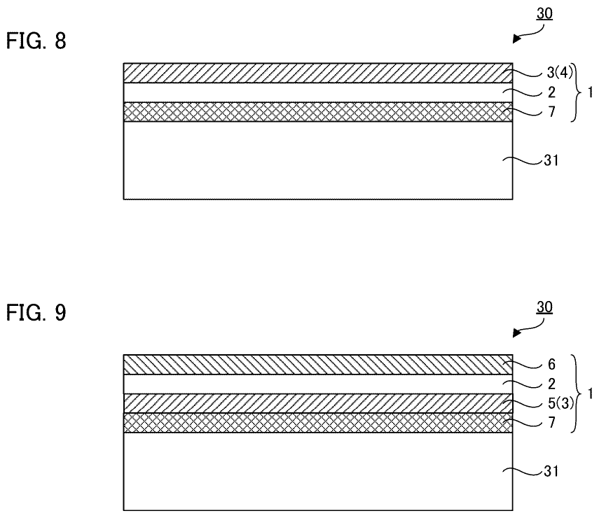

FIG. 8 and FIG. 9 are schematic cross-sectional views illustrating an example of a display device in the present disclosure. As shown in FIG. 8 and FIG. 9, display device 30 comprises display panel 31, and the stacked body for a display device 1 placed on an observer side of the display panel 31. In the display device 30, the stacked body for a display device 1 and the display panel 31 may be adhered via, for example, the adhesive layer for adhesion 7 of the stacked body for a display device 1.

In the present disclosure, when the stacked body for a display device includes, for example, a polyimide substrate, and an ultraviolet absorber-containing hard coating layer placed on surface of the polyimide substrate, and when the stacked body for a display device is placed on the surface of the display device, as shown in FIG. 8, it is placed so that the ultraviolet absorber-containing hard coating layer 4 is on the outer side, and the polyimide substrate 2 is on the inner side.

Also, in the present disclosure, when the stacked body for a display device includes, for example, an ultraviolet absorbing layer, a polyimide substrate, and a hard coating layer in this order, and when the stacked body for a display device is placed on the surface of the display device, as shown in FIG. 9, it is placed so that the hard coating layer 6 is on the outer side, and the ultraviolet absorbing layer 5 is on the inner side.

The method for placing the stacked body for a display device in the present disclosure on the surface of the display device is not particularly limited, and examples thereof may include a method via an adhesive layer.

Examples of the display panel in the present disclosure may include a display panel used for a display device such as an organic EL display device, and a liquid crystal display device.

The display device in the present disclosure may include a touch-sensitive panel member between the display panel and the stacked body for a display device.

Among the above, the display device in the present disclosure is preferably a flexible display device such as a foldable display, a rollable display, and a bendable display.

Also, the display device in the present disclosure is preferably foldable. That is, the display device in the present disclosure is preferably a foldable display. The display device in the present disclosure has excellent bending resistance, so that it is suitable for a foldable display.

Also, among them, the display device in the present disclosure is preferably an organic EL display device including no circular polarizing plate. Since the display device in the present disclosure is able to suppress ultraviolet ray deterioration and is able to suppress the decrease in the bending properties, when the display device is an organic EL display device including no circular polarizing plate, deterioration due to light emission from external light or organic EL element may be suppressed, and good bending properties may be obtained.

Incidentally, the present disclosure is not limited to the embodiments. The embodiments are exemplification, and any other variations are intended to be included in the technical scope of the present disclosure if they have substantially the same constitution as the technical idea described in the claim of the present disclosure and offer similar operation and effect thereto.

### EXAMPLES

The present disclosure is hereinafter explained in further details with reference to Examples and Comparative Examples.

### Example 1

### (1) Preparation of Acrylic Polymer 1

Firstly, a condenser with a ball, a mercury thermometer, and a stirring device were installed in a 200 mL four-necked flask. Then, 4.0 g (0.013 mol) of 6-[5-(2-hydroxyethyl)-2H-benzotriazole-2-yl]benzo[1,3]dioxole-5-ol, 40 mL of toluene, 1.8 g (0.021 mol) of methacrylic acid, and 0.4 g (0.004 mol) of methanesulfonic acid were added, and reflux dehydrated for 4 hours at 110° C. to 115° C. Then, 30 mL of water and 0.6 g (0.006 mol) of sodium carbonate were added, and the reflux stirred to decolor. After filtration, 40 mL of toluene was recovered from the filtrate by decompression; 100 mL of isopropyl alcohol was added; the precipitated crystal was filtered; and it was washed with 40 mL of isopropyl alcohol. Then, 4.2 g of yellow crystal was obtained by drying at 40° C. under reduced pressure. 4.2 g of this yellow crystal was repulp washed with isopropyl alcohol and dried at 40° C. under reduced pressure. Thereby, as a sesamol-type benzotriazole based compound, 3.4 g of 2-[2-(6-hydroxybenzo[1,3]dioxole-5-yl)-2H-benzotriazole-5-yl]ethyl methacrylate was obtained.

Then, a Dimroth condenser, a mercury thermometer, a nitrogen gas blowing tube, and a stirring device were installed in a four-necked flask. Then, 16 parts by mass of the synthesized 2-[2-(6-hydroxybenzo[1,3]dioxole-5-yl)-2H-benzotriazole-5-yl]ethyl methacrylate, 24 parts by mass of methyl methacrylate (MMA) as another monomer, 20 parts by mass of toluene, 20 parts by mass of ethyl methyl ketone as solvents, and 0.6 parts by mass of 1,1′-azobis(cyclohexane-1-carbonitrile) as polymerization initiator were added; inside of the flask was nitrogen substituted for 1 hour at nitrogen gas flow rate of 10 mL/min while stirring; and then, a polymerization reaction was carried out at reacting liquid temperature of 90° C. to 96° C. for 10 hours under refluxing condition.

After the polymerization reaction, 10 parts by mass of toluene and 10 parts by mass of methyl ethyl ketone (MEK) were added to obtain 100.6 parts by mass of a solution including acrylic polymer 1 (ultraviolet absorber 1) wherein sesamol-type benzotriazole based compound was reacted and bonded to MMA.

### (2) Formation of Ultraviolet Absorber-Containing Hard Coating Layer

The acrylic polymer 1 (ultraviolet absorber 1) and ethoxylated dipentaerythritol polyacrylate (“A-DPH-12E” from Shin-Nakamura Chemical Co., Ltd.) were mixed at a solid content mass ratio of 20:100. To 120 parts by mass of the obtained mixture, 6 parts by mass of a polymerization initiator (“Omnirad819” from IGM Resins B. V.) and 0.3 parts by mass of a leveling agent (“F-568” from DIC Corporation) were added; and methyl ethyl ketone (MEK) was added so that the solid content concentration was 30%, to prepare a resin composition for ultraviolet absorber-containing hard coating layer 1.

Then, using a polyimide film (“Neopulim” from Mitsubishi Gas Chemical Company, Inc.) having a thickness of 50 μm as a polyimide substrate, a coating film was formed on the polyimide substrate by applying the resin composition for an ultraviolet absorber-containing hard coating layer 1 with a bar coater. Thereafter, the coating film was heated at 70° C. for 1 minute to evaporate the solvent in the coating film, and the coating film was cured by irradiating ultraviolet rays with an ultraviolet ray irradiation device (light source H bulb from Fusion UV Systems Japan K. K.) under the condition of an oxygen concentration of 200 ppm or less so that the integrated light amount was 400 mJ/cm² to form an ultraviolet absorber-containing hard coating layer with a thickness of 9.0 μm. Thereby, a stacked body was obtained.

### Example 2

A stacked body was produced in the same manner as in Example 1 except that, the thickness of the ultraviolet absorber-containing hard coating layer was 7.5 μm.

### Example 3

A stacked body was produced in the same manner as in Example 1 except that, the thickness of the ultraviolet absorber-containing hard coating layer was 11.0 μm.

### Example 4

A stacked body was produced in the same manner as in Example 2 except that the ultraviolet absorber-containing hard coating layer was formed using the following resin composition for an ultraviolet absorber-containing hard coating layer 2.

### (Preparation of Resin Composition for Ultraviolet Absorber-Containing Hard Coating Layer 2)

The acrylic polymer 1 (ultraviolet absorber 1) and ethoxylated dipentaerythritol polyacrylate (“A-DPH-12E” from Shin-Nakamura Chemical Co., Ltd.) were mixed at a solid content mass ratio of 15:100. To 115 parts by mass of the obtained mixture, 6 parts by mass of a polymerization initiator (“Omnirad819” from IGM Resins B. V.) and 0.3 parts by mass of a leveling agent (“F-568” from DIC Corporation) were added; methyl ethyl ketone (MEK) was added so that the solid content concentration was 30%; and the mixture was stirred well to prepare a resin composition for ultraviolet absorber-containing hard coating layer 2.

### Example 5

A stacked body was produced in the same manner as in Example 3 except that the ultraviolet absorber-containing hard coating layer was formed using the following resin composition for an ultraviolet absorber-containing hard coating layer 3.

### (Preparation of Resin Composition for Ultraviolet Absorber-Containing Hard Coating Layer 3)

The acrylic polymer 1 (ultraviolet absorber 1) and ethoxylated dipentaerythritol polyacrylate (“A-DPH-12E” from Shin-Nakamura Chemical Co., Ltd.) were mixed at a solid content mass ratio of 30:100. To 130 parts by mass of the obtained mixture, 6 parts by mass of a polymerization initiator (“Omnirad819” from IGM Resins B. V.) and 0.3 parts by mass of a leveling agent (“F-568” from DIC Corporation) were added; methyl ethyl ketone (MEK) was added so that the solid content concentration was 30%; and the mixture was stirred well to prepare a resin composition for ultraviolet absorber-containing hard coating layer 3.

### Example 6

### (1) Formation of Hard Coating Layer

To 100 parts by mass of the ethoxylated dipentaerythritol polyacrylate (“A-DPH-12E” from Shin-Nakamura Chemical Co., Ltd.), 6 parts by mass of a polymerization initiator (“Omnirad819” from IGM Resins B. V.) and 0.3 parts by mass of a leveling agent (“F-568” from DIC Corporation) were added; methyl ethyl ketone (MEK) was added so that the solid content concentration was 30%; and the mixture was stirred well to prepare a resin composition for hard coating layer 1.

Using a polyimide film (“Neopulim” from Mitsubishi Gas Chemical Company, Inc.) having a thickness of 50 μm as a polyimide substrate, a coating film was formed on the polyimide substrate by applying the resin composition for a hard coating layer 1 with a bar coater. Thereafter, the coating film was heated at 70° C. for 1 minute to evaporate the solvent in the coating film, and the coating film was cured by irradiating ultraviolet rays with an ultraviolet ray irradiation device (light source H bulb from Fusion UV Systems Japan K.K.) under the condition of an oxygen concentration of 200 ppm or less so that the integrated light amount was 400 mJ/cm² to form a hard coating layer with a thickness of 12.0 μm.

### (2) Formation of Ultraviolet Absorbing Layer

The pentaerythritol EO modified tetraacrylate (“MIRAMER M4004” from Toyo Chemicals Co., Ltd.) and the acrylic polymer 1 (ultraviolet absorber 1) were mixed at a solid content mass ratio of 100:50. To 150 parts by mass of the obtained mixture, 6 parts by mass of a polymerization initiator (“Omnirad819” from IGM Resins B. V.) and 0.3 parts by mass of a leveling agent (“F-568” from DIC Corporation) were added; methyl ethyl ketone (MEK) was added so that the solid content concentration was 30%; and the mixture was stirred well to prepare a resin composition for ultraviolet absorbing layer 1.

A coating film was formed on the polyimide substrate, on opposite surface to the hard coating layer, by applying the resin composition for an ultraviolet absorbing layer 1. Thereafter, the coating film was heated at 70° C. for 1 minute to evaporate the solvent in the coating film, and the coating film was cured by irradiating ultraviolet rays with an ultraviolet ray irradiation device (light source H bulb from Fusion UV Systems Japan K.K.) under the condition of an oxygen concentration of 200 ppm or less so that the integrated light amount was 400 mJ/cm² to form an ultraviolet absorbing layer with a thickness of 3.0 μm.

### Example 7

A stacked body was produced in the same manner as in Example 6 except that the ultraviolet absorbing layer was formed using the following resin composition for an ultraviolet absorbing layer 2.

### (Preparation of Resin Composition for Ultraviolet Absorbing Layer 2)

The pentaerythritol EO modified tetraacrylate (“MIRAMER M4004” from Toyo Chemicals Co., Ltd.) and the acrylic polymer 1 (ultraviolet absorber 1) were mixed at a solid content mass ratio of 100:40. To 140 parts by mass of the obtained mixture, 6 parts by mass of a polymerization initiator (“Omnirad819” from IGM Resins B. V.) and 0.3 parts by mass of a leveling agent (“F-568” from DIC Corporation) were added; methyl ethyl ketone (MEK) was added so that the solid content concentration was 30%; and the mixture was stirred well to prepare a resin composition for ultraviolet absorbing layer 2.

### Example 8

A stacked body was produced in the same manner as in Example 6 except that, the thickness of the ultraviolet absorbing layer was 4.0 μm.

### Example 9

A stacked body was produced in the same manner as in Example 6 except that the ultraviolet absorbing layer was formed using the following resin composition for an ultraviolet absorbing layer 3.

### (Preparation of Resin Composition for Ultraviolet Absorbing Layer 3)

The pentaerythritol EO modified tetraacrylate (“MIRAMER M4004” from Toyo Chemicals Co., Ltd.) and the acrylic polymer 1 (ultraviolet absorber 1) were mixed at a solid content mass ratio of 100:25. To 125 parts by mass of the obtained mixture, 6 parts by mass of a polymerization initiator (“Omnirad819” from IGM Resins B. V.) and 0.3 parts by mass of a leveling agent (“F-568” from DIC Corporation) were added; methyl ethyl ketone (MEK) was added so that the solid content concentration was 30%; and the mixture was stirred well to prepare a resin composition for ultraviolet absorbing layer 3.

### Example 10

A stacked body was produced in the same manner as in Example 6 except that, the thickness of the ultraviolet absorbing layer was 5.0 μm.

### Example 11

### (1) Formation of Ultraviolet Absorber-Containing Hard Coating Layer

The pentaerythritol EO modified tetraacrylate (“MIRAMER M4004” from Toyo Chemicals Co., Ltd.) and the acrylic polymer 1 (ultraviolet absorber 1) were mixed at a solid content mass ratio of 100:20. To 120 parts by mass of the obtained mixture, 6 parts by mass of a polymerization initiator (“Omnirad819” from IGM Resins B. V.) and 0.3 parts by mass of a leveling agent (“F-568” from DIC Corporation) were added; methyl ethyl ketone (MEK) was added so that the solid content concentration was 30%; and the mixture was stirred well to prepare a resin composition for ultraviolet absorber-containing hard coating layer 4.

As the polyimide substrate, a polyimide film (“Neopulim” from Mitsubishi Gas Chemical Company, Inc.) having a thickness of 50 μm was used. A coating film was formed on the polyimide substrate by applying the resin composition for an ultraviolet absorber-containing hard coating layer 4. Thereafter, the coating film was heated at 70° C. for 1 minute to evaporate the solvent in the coating film, and the coating film was cured by irradiating ultraviolet rays with an ultraviolet ray irradiation device (light source H bulb from Fusion UV Systems Japan K.K.) under the condition of an oxygen concentration of 200 ppm or less so that the integrated light amount was 400 mJ/cm² to form an ultraviolet absorbing layer with a thickness of 9.0 μm.

### (2) Formation of Second Hard Coating Layer

A resin composition for a hard coating layer 1 was prepared in the same manner as in Example 6. A coating film was formed on the polyimide substrate, on opposite surface to the ultraviolet absorber-containing hard coating layer by applying the resin composition for a hard coating layer 1 with a bar coater. Thereafter, the coating film was heated at 70° C. for 1 minute to evaporate the solvent in the coating film, and the coating film was cured by irradiating ultraviolet rays with an ultraviolet ray irradiation device (light source H bulb from Fusion UV Systems Japan K.K.) under the condition of an oxygen concentration of 200 ppm or less so that the integrated light amount was 400 mJ/cm² to form a second hard coating layer with a thickness of 3.0 μm.

### Comparative Example 1

A stacked body was produced in the same manner as in Example 6 except that the ultraviolet absorbing layer was not formed.

### Comparative Example 2

A stacked body was produced in the same manner as in Example 4 except that the thickness of the ultraviolet absorber-containing hard coating layer was 6.0 μm.

### Comparative Example 3

A stacked body was produced in the same manner as in Example 6 except that the ultraviolet absorbing layer was formed using the following resin composition for an ultraviolet absorbing layer 4.

### (Preparation of Resin Composition for Ultraviolet Absorbing Layer 4)

The pentaerythritol EO modified tetraacrylate (“MIRAMER M4004” from Toyo Chemicals Co., Ltd.) and the acrylic polymer 1 (ultraviolet absorber 1) were mixed at a solid content mass ratio of 100:20. To 120 parts by mass of the obtained mixture, 6 parts by mass of a polymerization initiator (“Omnirad819” from IGM Resins B. V.) and 0.3 parts by mass of a leveling agent (“F-568” from DIC Corporation) were added; methyl ethyl ketone (MEK) was added so that the solid content concentration was 30%; and the mixture was stirred well to prepare a resin composition for ultraviolet absorbing layer 4.

### [Evaluation]

### (1) Difference of Crack Elongation Before and After Light Resistance Test

The following light resistance test was carried out to the stacked body, the crack elongation before and after the light resistance test was measured by the following method, and the difference of the crack elongation before and after the light resistance test was determined.

### (Light Resistance Test)

In Examples 1 to 5 and 11, and Comparative Example 2, xenon light was irradiated from the ultraviolet absorber-containing hard coating layer side surface of the stacked body. In Examples 6 to 10 and Comparative Example 3, xenon light was irradiated from the ultraviolet absorbing layer side surface of the stacked body. In Comparative Example 1, xenon light was irradiated from the hard coating layer side surface of the stacked body. The test conditions in each of the above were: temperature of 50° C., humidity of 50% RH, wavelength range of 300 nm or more and 400 nm or less, radiation illuminance of 60 W/m² and irradiation time of 60 hours. A xenon weatherometer (“Ci4000” from Atlas Material Testing Technology) was used for the light resistance test.

### (Crack Elongation)

Firstly, the stacked body was cut into a size of 3 mm×100 mm to prepare a test piece. Then, using a Tensilon universal testing instrument “STA-1150” from Orientec Co., Ltd., the test piece was installed so that the distance between the clamps (distance between grips) was 50 mm and there was no deflection, the test piece was continued to be pulled at a temperature of 23±5° C., humidity of 30% RH or more and 70% RH or less and pulling speed of 10 mm/minute until a crack occurred in the stacked body, and tensile length when the crack occurred in the stacked body was measured. The presence of the crack was determined visually by irradiating the test piece with an LED. Then, the crack elongation was calculated from the following formula (1).

$$Crack elongation ( \% ) = 100 \times tensile length ( mm ) / distance between grips ( mm ) \qquad ( 1 )$$

Then, the difference of the crack elongation before and after the light resistance test was determined from the following formula (2).

$$Difference of crack elongation before and after light resistance test = crack elongation before light resistance test ( \% ) - crack elongation after light resistance test ( \% ) \qquad ( 2 )$$

(2) Crack Elongation after Light Resistance Test

The light resistance test described above was carried out to the stacked body, and the crack elongation after the light resistance test was measured by the method described above.

### (3) Yellowness Before Light Resistance Test

The yellowness (YI) was determined according to JIS K7373:2006. Specifically, based on the transmittance measured using an ultraviolet-visible and near-infrared spectrophotometer (“V-7100” from JASCO Corporation) by a spectrophotometric colorimetry; using a deuterium lamp and a tungsten halogen lamp; with 0.5 nm interval in the range from 300 nm or more and 780 nm or less; in conditions of a viewing angle of 2 degrees, and standard light C, the tristimulus values X, Y and Z in the XYZ color system were determined, and the yellowness was calculated from the following formula, from the values of X, Y, and Z. Also, the following conditions were used for measuring the yellowness.

$$YI = 100 ( 1.2 \; 769 X - 1.0592 Z ) / Y \qquad ( 3 )$$

### (Measurement Conditions)

Viewing angle: 2°
Illuminant: C
Light source: deuterium lamp and tungsten halogen lamp
Wavelength range: 0.5 nm interval in the range of 300 nm or more and 780 nm or less
Scan speed: fast
Slit width: 5.0 nm
S/R switch: standard
Auto Zero: carried out at 550 nm after baseline scan

### (4) Dynamic Bending Property

The following dynamic bending test was carried out to the stacked body to evaluate the bending resistance. Firstly, a stacked body having a size of 20 mm×100 mm was prepared. Then, as shown in FIG. 2A, short side portion 1C and short side portion 1D, opposing to the short side portion 1C, of the stacked body for a display device 1 were respectively fixed by parallelly arranged fixing portions 51 in a durability tester (product name “DLDMLH-FS” from Yuasa Co., Ltd.). Then, as shown in FIG. 2B, by moving the fixing portions 51 so as to be closer to each other, the stacked body for a display device 1 was deformed so as to be folded. Further, as shown in FIG. 2C, after moving the fixing portions 51 to the position wherein distance “d” between the two opposing short side portions 1C and 1D of the stacked body for a display device 1 fixed by the fixing portions 51 was a predetermined value, the deformation of the stacked body for a display device 1 was dissolved by moving the fixing portions 51 in opposite directions. As shown in FIGS. 2A to 2C, by moving the fixing portions 51, the stacked body for a display device 1 was folded into 180° repeatedly for 200,000 times. When doing so, the distance “d” between the two opposing short side portions 1C and 1D of the stacked body for a display device 1 was 4 mm, 6 mm or 8 mm. Also, the stacked body was bent so that the ultraviolet absorbing layer was outward. The results of the dynamic bending test were evaluated based on the following criteria.
A: no crack or fracture occurred in the stacked body even the stacked body was bent for 200,000 times, when the distance “d” between the short side portions 1C and 1D was 4 mm
B: although a crack or a fracture occurred in the stacked body until the stacked body was bent for 200,000 times, when the distance “d” between the short side portions 1C and 1D was 4 mm; no crack or fracture occurred in the stacked body even the stacked body was bent for 200,000 times, when the distance “d” between the short side portions 1C and 1D was 6 mm
C: although a crack or a fracture occurred in the stacked body until the stacked body was bent for 200,000 times, when the distance “d” between the short side portions 1C and 1D was 6 mm; no crack or fracture occurred in the stacked body even the stacked body was bent for 200,000 times, when the distance “d” between the short side portions 1C and 1D was 8 mm
D: a crack or a fracture occurred in the stacked body until the stacked body was bent for 200,000 times, when the distance “d” between the short side portions 1C and 1D was 8 mm

### (5) IR Spectrum

In Examples 1 to 5 and 11, and Comparative Example 2, the stacked body was cut out into a size of 10 cm×10 cm, IR spectra were measured, using the ultraviolet absorber-containing hard coating layer surface of the stacked body as the measuring surface. Incidentally, for Example 11, the IR spectra were measured before the second hard coating layer was formed. For Examples 6 to 10 and Comparative Example 3, the stacked body was cut out into a size of 10 cm×10 cm, IR spectra were measured, using the ultraviolet absorbing layer surface of the stacked body as the measuring surface. The IR spectra were measured by one-time reflection ATR method using Fourier transform infrared spectrophotometer (FT-IR) under the following conditions.

### (Measurement Conditions)

Spectrometer: Fourier transform infrared spectrophotometer FTS-7000 (from Digital Laboratory, Inc.)
Accessory device: attachment for single-reflection ATR: Silver Gate Evolution (from Specac Ltd.)
Prism: Ge crystal
Incident angle: 45° incident
Measuring wavenumber range: from 700 cm⁻¹ to 4000 cm⁻¹
Resolution: 4 cm⁻¹
Scan speed: 20 kHz
Cumulative number: 64 times

Then, in an IR spectrum, a ratio of the peak strength of the peak deriving from a triazole ring included in the ultraviolet absorber with respect to the peak strength of the peak deriving from a carbonyl bond was determined.

### (6) TOF-SIMS

Using a time-of-flight secondary ion mass spectrometer (“TOF. SIMS5” from IONTOF GmbH), the secondary ion intensity deriving from the ultraviolet absorber in each layer was measured for the stacked bodies in Examples 1 and 11. Specifically, the stacked body was firstly cut out into a size of 10 mm×10 mm. Then, the stacked body was placed in the sample room of the time-of-flight secondary ion mass spectrometer so that the primary ions were irradiated to the surface of the ultraviolet absorber-containing hard coating layer or the second hard coating layer of the stacked body. Then, the depth profile was obtained by measuring the secondary ion intensity deriving from the ultraviolet absorber, under the following measurement conditions. Incidentally, the secondary ion deriving from the ultraviolet absorber 1 was regarded as C₆H₄N₃⁻.

### (7) Pencil Hardness

The pencil hardness was measured on the ultraviolet absorber-containing hard coating layer side surface or the second hard coating layer side surface of the stacked body in accordance with JIS K5600-5-4:1999. In the measurement, as the pencil hardness tester, “Pencil Scratch Hardness Tester (electric powered)” from Toyo Seiki Seisaku-sho, Ltd. was used. The measurement conditions were angle of 45°, load of 1 kg, testing rate of 0.5 mm/second or more and 1 mm/second or less, and temperature of 23±2° C.

### (8) Steel Wool Resistance

Using #0000 steel wool (“Bonstar” from Nippon Steel Wool Co., Ltd.), the ultraviolet absorber-containing hard coating layer side surface or the second hard coating layer side surface of the stacked body was rubbed for a stroke under load of 1 kg/cm², at speed of 50 mm/second. Then, the presence or absence of scratches on the surface of the stacked body was confirmed visually.

TABLE 1

| | Example 1 | Example 2 | Example 3 | Example 4 | Example 5 | Example 6 | Example 7 |
|---|---|---|---|---|---|---|---|
| Layer structure | UV absorber-containing HC layer/PI substrate | | | | | HC layer/PI substrate/UV absorbing layer | |
| PI substrate thk (μm) | 50 | 50 | 50 | 50 | 50 | 50 | 50 |
| UV abs-cong HC layer | 9.0 | 7.5 | 11.0 | 7.5 | 11.0 | — | — |
| thickness [symbol] (μm) | | | | | | | |
| UV absorber content in UV | 20 | 20 | 20 | 15 | 30 | — | — |
| abs-cong HC layer | | | | | | | |
| (parts by mass) | | | | | | | |
| UV abs-cong HC ly thk × | 180 | 150 | 220 | 112.5 | 330 | — | — |
| UV absober content | | | | | | | |
| IR spectrum pk str ratio | 0.69 | 0.69 | 0.69 | 0.55 | 0.98 | — | — |
| of UV abs-cong HC ly | | | | | | | |
| UV abs-cong HC ly thk × | 6.2 | 5.2 | 7.6 | 4.1 | 10.8 | — | — |
| IR spectrum pk str ratio | | | | | | | |
| UV absorbing layer | — | — | — | — | — | 3.0 | 3.0 |
| thickness (μm) | | | | | | | |
| UV absorber content in | — | — | — | — | — | 50 | 40 |
| UV absorbing layer | | | | | | | |
| (parts by mass) | | | | | | | |
| UV abs-cong HC ly thk × | — | — | — | — | — | 150 | 120 |
| UV absorber content | | | | | | | |
| IR spectrum pk str ratio | — | — | — | — | — | 1.55 | 1.26 |
| of UV absorbing layer | | | | | | | |
| UV abs layer thk × IR | — | — | — | — | — | 4.7 | 3.8 |
| spectrum pk str ratio | | | | | | | |
| HC layer thk (μm) | — | — | — | — | — | 12.0 | 12.0 |
| Crack elongation diff | 0.1 | 0.3 | 0.1 | 0.6 | 0.1 | 0.1 | 0.4 |
| pre/post lt resist test (%) | | | | | | | |
| Crack elongation after | 4.7 | 4.2 | 4.5 | 4.8 | 5.0 | 4.6 | 4.0 |
| light resistance test (%) | | | | | | | |
| YI bef lt resist test | 7.4 | 4.2 | 9.5 | 3.2 | 14.4 | 6.8 | 4.0 |
| Bend prop aft lt resist test | A | B | B | C | C | A | B |

| | | | | | Comp Ex 2 | Comp Ex 3 |
|---|---|---|---|---|---|---|
| | | | | Comp Ex 1 | UV abs- | HC ly/ |
| | Example 8 | Example 9 | Example 10 | HC layer/ | cong HC ly/ | PI subst./ |
| Layer structure | HC layer/PI substrate/UV absorbing layer | | | PI subst. | PI subst. | UV abs. ly |
| PI substrate thk (μm) | 50 | 50 | 50 | 50 | 50 | 50 |
| UV abs-cong HC layer | — | — | — | — | 6.0 | — |
| thickness [symbol] (μm) | | | | | | |
| UV absorber content in UV | — | — | — | — | 15 | — |
| abs-cong HC layer | | | | | | |
| (parts by mass) | | | | | | |
| UV abs-cong HC ly thk × | — | — | — | — | 90 | — |
| UV absober content | | | | | | |
| IR spectrum pk str ratio | — | — | — | — | 0.55 | — |
| of UV abs-cong HC ly | | | | | | |
| UV abs-cong HC ly thk × | — | — | — | — | 3.3 | — |
| IR spectrum pk str ratio | | | | | | |
| UV absorbing layer | 4.0 | 3.0 | 5.0 | — | — | 3.0 |
| thickness (μm) | | | | | | |
| UV absorber content in | 50 | 25 | 50 | — | — | 20 |
| UV absorbing layer | | | | | | |
| (parts by mass) | | | | | | |
| UV abs-cong HC ly thk × | 200 | 75 | 250 | — | — | 60 |
| UV absorber content | | | | | | |
| IR spectrum pk str ratio | 1.55 | 0.83 | 1.55 | — | — | 0.69 |
| of UV absorbing layer | | | | | | |
| UV abs layer thk × IR | 6.2 | 2.5 | 7.8 | — | — | 2.1 |
| spectrum pk str ratio | | | | | | |
| HC layer thk (μm) | 12.0 | 12.0 | 12.0 | 12.0 | — | 12.0 |
| Crack elongation diff | 0.1 | 0.6 | 0.1 | 1.0 | 0.8 | 0.8 |
| pre/post lt resist test (%) | | | | | | |
| Crack elongation after | 4.3 | 3.8 | 4.5 | 4.0 | 4.2 | 4.7 |
| light resistance test (%) | | | | | | |
| YI bef lt resist test | 8.9 | 3.1 | 13.9 | 2.6 | 2.5 | 2.3 |
| Bend prop aft lt resist test | B | C | C | D | D | D |

TABLE 2

| | Example 1 | Example 11 |
|---|---|---|
| Layer structure | UV abs-cong HC ly/PI substrate | 2nd HC ly/UV abs-cong HC ly/PI substrate |
| PI substrate thickness (μm) | 50 | 50 |
| UV abs-cong HC layer thickness (μm) | 9.0 | 9.0 |
| UV absorber content in UV absober-containing | 20 | 20 |
| HC layer (pt mass) | | |
| UV abs-cong HC ly thk × UV absober content | 180 | 180 |
| IR spectrum pk str ratio of UV abs-cong HC ly | 0.69 | 0.69 |
| UV abs-cong HC ly thk × IR spectrum pk str ratio | 6.2 | 6.2 |
| 2nd HC layer thickness (μm) | — | 3.0 |
| Crack elongation diff pre/post lt resist test (%) | 0.1 | 0.3 |
| Crack elongation after light resistance test (%) | 4.7 | 4.2 |
| YI before light resistance test | 7.4 | 7.8 |
| Bending property after light resistance test | A | B |
| Pencil hardness | 2H | 4H |
| SW resistance | No scratch for 100 strokes | No scratche for 1000 strokes |
| Ion intensity at depth of 1 μm from UV absorber- | — | 0.0 |
| containing HC layer side surface of 2nd HC layer/ion | | |
| intensity at depth of 1 μm from 2nd HC layer side surface | | |
| of UV absorber-containing HC layer | | |
| Ion intensity at depth of 1 μm from surface of UV | 1.00 | 0.78 |
| absorber-containing HC layer, opposite to PI substrate/ion | | |
| intensity at depth of 1 μm from PI substrate side surface | | |
| of UV absorber-containing HC ly | | |
| Ion intensity at depth of 1 μm from UV absorber- | 0.04 | 0.06 |
| containing HC layer side surface of substrate/ion | | |
| intensity at depth of 1 μm from substrate side surface | | |
| of UV absorber-containing HC layer | | |

The bending property of the stacked body in Examples 1 to 5 was excellent since the difference of the crack elongation before and after the light resistance test was a predetermined value or less; the crack elongation after the light resistance test was in a predetermined range; the product of the thickness of the ultraviolet absorber-containing hard coating layer, and the content of the ultraviolet absorber with respect to 100 parts by mass of the resin in the ultraviolet absorber-containing hard coating layer was in a predetermined range; or the product of the thickness of the ultraviolet absorber-containing hard coating layer, and the predetermined peak strength ratio in an IR spectrum of the ultraviolet absorber-containing hard coating layer was in a predetermined range. Also, the bending property of the stacked body in Examples 6 to 10 was excellent since the difference of the crack elongation before and after the light resistance test was a predetermined value or less; the crack elongation after the light resistance test was in a predetermined range; the product of the thickness of the ultraviolet absorbing layer, and the content of the ultraviolet absorber with respect to 100 parts by mass of the resin in the ultraviolet absorbing layer was in a predetermined range; or the product of the thickness of the ultraviolet absorbing layer, and the predetermined peak strength ratio in an IR spectrum of the ultraviolet absorbing layer was in a predetermined range. Meanwhile, the bending property of the stacked body in Comparative Examples 1 to 3 was inferior since the difference of the crack elongation before and after the light resistance test was high; or the crack elongation after the light resistance test was low. Also, the bending property of the stacked body in Comparative Example 2 was inferior since the product of the thickness of the ultraviolet absorber-containing hard coating layer, and the content of the ultraviolet absorber with respect to 100 parts by mass of the resin in the ultraviolet absorber-containing hard coating layer was low; or the product of the thickness of the ultraviolet absorber-containing hard coating layer, and the predetermined peak strength ratio in an IR spectrum of the ultraviolet absorber-containing hard coating layer was low. Also, the bending property of the stacked body in Comparative Example 3 was inferior since the product of the thickness of the ultraviolet absorbing layer, and the content of the ultraviolet absorber with respect to 100 parts by mass of the resin in the ultraviolet absorbing layer was low; or the product of the thickness of the ultraviolet absorbing layer, and the predetermined peak strength ratio in an IR spectrum of the ultraviolet absorbing layer was low.

Also, the bending property of the stacked body in Examples 1 to 3 was excellent since the yellowness before the light resistance test was in a preferable range; and the product of the thickness of the ultraviolet absorber-containing hard coating layer, and the content of the ultraviolet absorber with respect to 100 parts by mass of the resin in the ultraviolet absorber-containing hard coating layer was in a preferable range. Similarly, the bending property of the stacked body in Examples 6 to 8 was excellent since the yellowness before the light resistance test was in a preferable range; and the product of the thickness of the ultraviolet absorbing layer, and the content of the ultraviolet absorber with respect to 100 parts by mass of the resin in the ultraviolet absorbing layer was in a preferable range.

Also, from the results in Examples 1 to 5 and Comparative Example 2, it was indicated that, in order to obtain an excellent bending resistance, there is an optimum value in the product of the thickness of the ultraviolet absorber-containing hard coating layer, and the content of the ultraviolet absorber with respect to 100 parts by mass of the resin in the ultraviolet absorber-containing hard coating layer. Similarly, from the results in Examples 6 to 10 and Comparative Example 3, it was indicated that, in order to obtain an excellent bending resistance, there is an optimum value in the product of the thickness of the ultraviolet absorbing layer, and the content of the ultraviolet absorber with respect to 100 parts by mass of the resin in the ultraviolet absorbing layer.

Also, from the results in Examples 1 and 11, it was found out that, when a second hard coating layer is placed on the ultraviolet absorber-containing hard coating layer, on opposite side to the polyimide substrate, the surface hardness and the chafing resistance were improved. Also, from the TOF-SIMS results, it was suggested that the ultraviolet absorber was evenly distributed in the ultraviolet absorber-containing hard coating layer.

The present disclosure provides the following [1] to [17].

[1]

A stacked body for a display device comprising a polyimide substrate, and a functional layer including an ultraviolet absorber, placed on one surface of the polyimide substrate,
wherein a difference of a crack elongation of the stacked body for a display device measured by the following method, before and after the following light resistance test, is 0.6 or less.

Light resistance test: xenon light is irradiated for 60 hours from a functional layer side surface of the stacked body for a display device under conditions of a temperature of 50° C., humidity of 50% RH, wavelength range of 300 nm or more and 400 nm or less, and radiation illuminance of 60 W/m².

Method for measuring crack elongation: using a test piece of a size of 3 mm width and 100 mm length, a tensile length when a crack occurs in the stacked body for a display device is measured under conditions of a temperature of 23±5° C., humidity of 30% RH or more and 70% RH or less, pulling speed of 10 mm/minute, and a distance between grips of 50 mm. The crack elongation is calculated from the following formula (1).

$$Crack elongation ( \% ) = 100 \times tensile length ( mm ) / distance between grips ( mm ) \qquad ( 1 )$$

[2]

A stacked body for a display device comprising a polyimide substrate, and a functional layer including an ultraviolet absorber, placed on one surface of the polyimide substrate,
wherein a crack elongation of the stacked body for a display device measured by the following method, after the following light resistance test, is 3.0% or more and 6.0% or less.

Light resistance test: xenon light is irradiated for 60 hours from a functional layer side surface of the stacked body for a display device under conditions of a temperature of 50° C., humidity of 50% RH, wavelength range of 300 nm or more and 400 nm or less, and radiation illuminance of 60 W/m².

Method for measuring crack elongation: using a test piece of a size of 3 mm width and 100 mm length, a tensile length when a crack occurs in the stacked body for a display device is measured under conditions of a temperature of 23±5° C., humidity of 30% RH or more and 70% RH or less, pulling speed of 10 mm/minute, and a distance between grips of 50 mm. The crack elongation is calculated from the following formula (1).

$$Crack elongation ( \% ) = 100 \times tensile length ( mm ) / distance between grips ( mm ) \qquad ( 1 )$$

[3]

The stacked body for a display device according to [1] or [2], wherein the functional layer is an ultraviolet absorber-containing hard coating layer including the ultraviolet absorber and resin, and
a product of a content (parts by mass) of the ultraviolet absorber with respect to 100 parts by mass of the resin in the ultraviolet absorber-containing hard coating layer; and a thickness (μm) of the ultraviolet absorber-containing hard coating layer is 110 or more and 350 or less.

[4]

The stacked body for a display device according to any one of [1] to [3], wherein the functional layer is an ultraviolet absorber-containing hard coating layer including the ultraviolet absorber and resin, and
a product of a ratio, in an infrared absorption spectrum measured by an infrared spectroscopy of the ultraviolet absorber-containing hard coating layer, of a peak strength of a peak deriving from a triazole ring included in the ultraviolet absorber with respect to a peak strength of a peak deriving from a carbonyl bond; and a thickness (μm) of the ultraviolet absorber-containing hard coating layer is 4.1 or more and 10.8 or less.

[5]

The stacked body for a display device according to [1] or [2], wherein the functional layer is an ultraviolet absorbing layer including the ultraviolet absorber and resin,
a hard coating layer, the polyimide substrate, and the ultraviolet absorbing layer are placed in this order, and
a product of a content (parts by mass) of the ultraviolet absorber with respect to 100 parts by mass of the resin in the ultraviolet absorbing layer; and a thickness (μm) of the ultraviolet absorbing layer is 70 or more and 280 or less.

[6]

The stacked body for a display device according to [1], [2] or [5], wherein the functional layer is an ultraviolet absorbing layer including the ultraviolet absorber and resin,
a hard coating layer, the polyimide substrate, and the ultraviolet absorbing layer are placed in this order, and
a product of a ratio, in an infrared absorption spectrum measured by an infrared spectroscopy of the ultraviolet absorbing layer, of a peak strength of a peak deriving from a triazole ring included in the ultraviolet absorber with respect to a peak strength of a peak deriving from a carbonyl bond; and a thickness (μm) of the ultraviolet absorbing layer is 2.5 or more and 7.8 or less.

[7]

A stacked body for a display device comprising a polyimide substrate, and an ultraviolet absorber-containing hard coating layer including an ultraviolet absorber and resin, placed on one surface of the polyimide substrate,
wherein a product of a content (parts by mass) of the ultraviolet absorber with respect to 100 parts by mass of the resin in the ultraviolet absorber-containing hard coating layer; and a thickness (μm) of the ultraviolet absorber-containing hard coating layer is 110 or more and 350 or less.

[8]

A stacked body for a display device comprising a polyimide substrate, and an ultraviolet absorber-containing hard coating layer including an ultraviolet absorber and resin, placed on one surface of the polyimide substrate,
wherein a product of a ratio, in an infrared absorption spectrum measured by an infrared spectroscopy of the ultraviolet absorber-containing hard coating layer, of a peak strength of a peak deriving from a triazole ring included in the ultraviolet absorber with respect to a peak strength of a peak deriving from a carbonyl bond; and a thickness (μm) of the ultraviolet absorber-containing hard coating layer is 4.1 or more and 10.8 or less.

[9]

A stacked body for a display device comprising a hard coating layer, a polyimide substrate, and an ultraviolet absorbing layer including an ultraviolet absorber and resin, in this order,
wherein a product of a content (parts by mass) of the ultraviolet absorber with respect to 100 parts by mass of the resin in the ultraviolet absorbing layer; and a thickness (μm) of the ultraviolet absorbing layer is 70 or more and 280 or less.

[10]

A stacked body for a display device comprising a hard coating layer, a polyimide substrate, and an ultraviolet absorbing layer including an ultraviolet absorber and resin, in this order,
wherein a product of a ratio, in an infrared absorption spectrum measured by an infrared spectroscopy of the ultraviolet absorbing layer, of a peak strength of a peak deriving from a triazole ring included in the ultraviolet absorber with respect to a peak strength of a peak deriving from a carbonyl bond; and a thickness (μm) of the ultraviolet absorbing layer is 2.5 or more and 7.8 or less.

[11]

The stacked body for a display device according to any one of [1] to [10], wherein a yellowness index is 15.0 or less.

[12]

The stacked body for a display device according to any one of [1] to [4], or [11], wherein the functional layer is an ultraviolet absorber-containing hard coating layer including the ultraviolet absorber and resin, and
in the ultraviolet absorber-containing hard coating layer, when a secondary ion intensity of the ultraviolet absorber-containing hard coating layer in a depth direction is measured by a time-of-flight secondary ion mass spectrometry, a ratio of a secondary ion intensity, deriving from the ultraviolet absorber, at a depth of 1 μm from a surface of the ultraviolet absorber-containing hard coating layer, on opposite side to the polyimide substrate; with respect to a secondary ion intensity, deriving from the ultraviolet absorber, at a depth of 1 μm from a polyimide substrate side surface of the ultraviolet absorber-containing hard coating layer, is 0.7 or more and 1.5 or less.

[13]

The stacked body for a display device according to [7], [8] or [11], wherein, in the ultraviolet absorber-containing hard coating layer, when a secondary ion intensity of the ultraviolet absorber-containing hard coating layer in a depth direction is measured by a time-of-flight secondary ion mass spectrometry, a ratio of a secondary ion intensity, deriving from the ultraviolet absorber, at a depth of 1 μm from a surface of the ultraviolet absorber-containing hard coating layer, on opposite side to the polyimide substrate; with respect to a secondary ion intensity, deriving from the ultraviolet absorber, at a depth of 1 μm from a polyimide substrate side surface of the ultraviolet absorber-containing hard coating layer, is 0.7 or more and 1.5 or less.

[14]

The stacked body for a display device according to claim 1 or 2, wherein the functional layer is an ultraviolet absorber-containing hard coating layer including the ultraviolet absorber and resin, and
a hard coating film is placed on a surface of the ultraviolet absorber-containing hard coating layer, on opposite side to the polyimide substrate.

[15]

The stacked body for a display device according to [7], [8] or [11], wherein a hard coating film is placed on a surface of the ultraviolet absorber-containing hard coating layer, on opposite side to the polyimide substrate.

[16]

A display device comprising:
a display panel, and
the stacked body for a display device according to any one of [1] to [15]placed on an observer side of the display panel.

[17]

The display device according to [16], wherein the display device is an organic electroluminescence display device including no circular polarizing plate.

### REFERENCE SIGNS LIST

1: stacked body for a display device
2: polyimide substrate
3: functional layer
4: ultraviolet absorber-containing hard coating layer
5: ultraviolet absorbing layer
6: hard coating layer
7: hard coating film
8: adhesive layer
30: display device
31: display panel

1. A stacked body for a display device comprising a polyimide substrate, and a functional layer including an ultraviolet absorber, placed on one surface of the polyimide substrate,
wherein a difference of a crack elongation of the stacked body for a display device measured by the following method, before and after the following light resistance test, is 0.6 or less:
Light resistance test: xenon light is irradiated for 60 hours from a functional layer side surface of the stacked body for a display device under conditions of a temperature of 50° C., humidity of 50% RH, wavelength range of 300 nm or more and 400 nm or less, and radiation illuminance of 60 W/m²; and
Method for measuring crack elongation: using a test piece of a size of 3 mm width and 100 mm length, a tensile length when a crack occurs in the stacked body for a display device is measured under conditions of a temperature of 23±5° C., humidity of 30% RH or more and 70% RH or less, pulling speed of 10 mm/minute, and a distance between grips of 50 mm, with the crack elongation calculated from the following formula (1)
$$Crack elongation ( \% ) = 100 \times tensile length ( mm ) / distance between grips ( mm ) . \qquad ( 1 )$$

2. A stacked body for a display device comprising a polyimide substrate, and a functional layer including an ultraviolet absorber, placed on one surface of the polyimide substrate,
wherein a crack elongation of the stacked body for a display device measured by the following method, after the following light resistance test, is 3.0% or more and 6.0% or less:
Light resistance test: xenon light is irradiated for 60 hours from a functional layer side surface of the stacked body for a display device under conditions of a temperature of 50° C., humidity of 50% RH, wavelength range of 300 nm or more and 400 nm or less, and radiation illuminance of 60 W/m²; and
Method for measuring crack elongation: using a test piece of a size of 3 mm width and 100 mm length, a tensile length when a crack occurs in the stacked body for a display device is measured under conditions of a temperature of 23±5° C., humidity of 30% RH or more and 70% RH or less, pulling speed of 10 mm/minute, and a distance between grips of 50 mm, with the crack elongation calculated from the following formula (1)
$$Crack elongation ( \% ) = 100 \times tensile length ( mm ) / distance between grips ( mm ) . \qquad ( 1 )$$

3. The stacked body for a display device according to claim 1, wherein
the functional layer is an ultraviolet absorber-containing hard coating layer including the ultraviolet absorber and resin, and
a product of a content (parts by mass) of the ultraviolet absorber with respect to 100 parts by mass of the resin in the ultraviolet absorber-containing hard coating layer; and a thickness (μm) of the ultraviolet absorber-containing hard coating layer is 110 or more and 350 or less.

4. The stacked body for a display device according to claim 1, wherein
the functional layer is an ultraviolet absorber-containing hard coating layer including the ultraviolet absorber and resin, and
a product of a ratio, in an infrared absorption spectrum measured by an infrared spectroscopy of the ultraviolet absorber-containing hard coating layer, of a peak strength of a peak deriving from a triazole ring included in the ultraviolet absorber with respect to a peak strength of a peak deriving from a carbonyl bond; and a thickness (μm) of the ultraviolet absorber-containing hard coating layer is 4.1 or more and 10.8 or less.

5. The stacked body for a display device according to claim 1, wherein
the functional layer is an ultraviolet absorbing layer including the ultraviolet absorber and resin,
a hard coating layer, the polyimide substrate, and the ultraviolet absorbing layer are placed in this order, and
a product of a content (parts by mass) of the ultraviolet absorber with respect to 100 parts by mass of the resin in the ultraviolet absorbing layer, and a thickness (μm) of the ultraviolet absorbing layer is 70 or more and 280 or less.

6. The stacked body for a display device according to claim 1, wherein
the functional layer is an ultraviolet absorbing layer including the ultraviolet absorber and resin,
a hard coating layer, the polyimide substrate, and the ultraviolet absorbing layer are placed in this order, and
a product of a ratio, in an infrared absorption spectrum measured by an infrared spectroscopy of the ultraviolet absorbing layer, of a peak strength of a peak deriving from a triazole ring included in the ultraviolet absorber with respect to a peak strength of a peak deriving from a carbonyl bond, and a thickness (μm) of the ultraviolet absorbing layer is 2.5 or more and 7.8 or less.

7. A stacked body for a display device comprising a polyimide substrate, and an ultraviolet absorber-containing hard coating layer including an ultraviolet absorber and resin, placed on one surface of the polyimide substrate,
wherein a product of a content (parts by mass) of the ultraviolet absorber with respect to 100 parts by mass of the resin in the ultraviolet absorber-containing hard coating layer; and a thickness (μm) of the ultraviolet absorber-containing hard coating layer is 110 or more and 350 or less.

8. A stacked body for a display device comprising a polyimide substrate, and an ultraviolet absorber-containing hard coating layer including an ultraviolet absorber and resin, placed on one surface of the polyimide substrate,
wherein a product of a ratio, in an infrared absorption spectrum measured by an infrared spectroscopy of the ultraviolet absorber-containing hard coating layer, of a peak strength of a peak deriving from a triazole ring included in the ultraviolet absorber with respect to a peak strength of a peak deriving from a carbonyl bond; and a thickness (μm) of the ultraviolet absorber-containing hard coating layer is 4.1 or more and 10.8 or less.

9. A stacked body for a display device comprising a hard coating layer, a polyimide substrate, and an ultraviolet absorbing layer including an ultraviolet absorber and resin, in this order,
wherein a product of a content (parts by mass) of the ultraviolet absorber with respect to 100 parts by mass of the resin in the ultraviolet absorbing layer; and a thickness (μm) of the ultraviolet absorbing layer is 70 or more and 280 or less.

10. A stacked body for a display device comprising a hard coating layer, a polyimide substrate, and an ultraviolet absorbing layer including an ultraviolet absorber and resin, in this order,
wherein a product of a ratio, in an infrared absorption spectrum measured by an infrared spectroscopy of the ultraviolet absorbing layer, of a peak strength of a peak deriving from a triazole ring included in the ultraviolet absorber with respect to a peak strength of a peak deriving from a carbonyl bond; and a thickness (μm) of the ultraviolet absorbing layer is 2.5 or more and 7.8 or less.

11. The stacked body for a display device according to claim 1, wherein a yellowness index is 15.0 or less.

12. The stacked body for a display device according to claim 1, wherein
the functional layer is an ultraviolet absorber-containing hard coating layer including the ultraviolet absorber and resin, and
in the ultraviolet absorber-containing hard coating layer, when a secondary ion intensity of the ultraviolet absorber-containing hard coating layer in a depth direction is measured by a time-of-flight secondary ion mass spectrometry, a ratio of a secondary ion intensity, deriving from the ultraviolet absorber, at a depth of 1 μm from a surface of the ultraviolet absorber-containing hard coating layer, on opposite side to the polyimide substrate; with respect to a secondary ion intensity, deriving from the ultraviolet absorber, at a depth of 1 μm from a polyimide substrate side surface of the ultraviolet absorber-containing hard coating layer, is 0.7 or more and 1.5 or less.

13. The stacked body for a display device according to claim 7, wherein, in the ultraviolet absorber-containing hard coating layer, when a secondary ion intensity of the ultraviolet absorber-containing hard coating layer in a depth direction is measured by a time-of-flight secondary ion mass spectrometry, a ratio of a secondary ion intensity, deriving from the ultraviolet absorber, at a depth of 1 μm from a surface of the ultraviolet absorber-containing hard coating layer, on opposite side to the polyimide substrate; with respect to a secondary ion intensity, deriving from the ultraviolet absorber, at a depth of 1 μm from a polyimide substrate side surface of the ultraviolet absorber-containing hard coating layer, is 0.7 or more and 1.5 or less.

14. The stacked body for a display device according to claim 1, wherein
the functional layer is an ultraviolet absorber-containing hard coating layer including the ultraviolet absorber and resin, and
a hard coating film is placed on a surface of the ultraviolet absorber-containing hard coating layer, on opposite side to the polyimide substrate.

15. The stacked body for a display device according to claim 7, wherein a hard coating film is placed on a surface of the ultraviolet absorber-containing hard coating layer, on opposite side to the polyimide substrate.

16. A display device comprising:
a display panel, and
the stacked body for a display device according to claim 1 placed on an observer side of the display panel.

17. The display device according to claim 16, wherein the display device is an organic electroluminescence display device including no circular polarizing plate.
